(19) United States
(12) Patent Application Publication
(10) Pub. No.: US 2005/0285128 A1
(43) Pub. Date: Dec. 29, 2005

(54) Surface plasmon light emitter structure and method of manufacture

(75) Inventors: Axel Scherer, Laguna Beach, CA (US); Koichi Okamoto, Pasadena, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: California Institute of Technology, Pasadena, CA (US)

(21) Appl. No.: 11/055,005

(22) Filed: Feb. 9, 2005

Related U.S. Application Data
(60) Provisional application No. 60/543,127, filed on Feb. 10, 2004.

(51) Int. Cl. H01L 29/22

(52) U.S. Cl. 257/98

(57) ABSTRACT

A method (and resulting structures) for manufacturing light emitting semiconductor devices. The method includes providing a substrate comprising a surface region and forming a metal layer overlying the surface region of the substrate. In a specific embodiment, the metal layer and the surface region are characterized by a spatial spacing between the metal layer and the substrate to cause a coupling between electron-hole pairs generated in the substrate and a surface plasmon mode at an interface region between the metal layer and the surface region. Additionally, the interface region has a textured characteristic between the surface region and the metal layer. The textured characteristics causes emission of electromagnetic radiation through the surface plasmon mode or like mechanism according to a specific embodiment.

### CROSS-REFERENCES TO RELATED APPLICATIONS

The present application claims priority to U.S. Provisional Application Ser. No. 60/543,127 (Caltech Docket Number CIT 4041) filed Feb. 10, 2004, commonly assigned, and hereby incorporated by reference herein.

### STATEMENT AS TO RIGHTS TO INVENTIONS MADE UNDER FEDERALLY SPONSORED RESEARCH OR DEVELOPMENT

Certain rights to the invention herein may be subject to rights under Government Grant AFOSR under Contract Number F49620-03-1-0418.

### BACKGROUND OF THE INVENTION

The present invention relates generally to emission of electromagnetic radiation using light emitting diodes and their methods of manufacture. More particularly, the present invention provides a method and structure for a light emitting diode having enhanced characteristics by surface plasmon coupling. Merely by way of example, the invention has been applied to indium gallium nitride (“InGaN”) quantum wells, but it would be recognized that the invention has a much broader range of applicability. For example, the invention can be applied to other semiconductor materials such as silicon (Si), germanium (Ge), silicon carbide (SiC), gallium nitride (GaN), indium gallium nitride (InGaN), aluminum gallium nitride (AlGaN), zinc selenium (ZnSe), zinc cadminum selenium (ZnCdSe), gallium arsenide (GaAs), aluminum gallium arsenide (AlGaAs), indium gallium srdenide (InGaN), gallium phosphide (GaP), indium gallium aluminum phosphide (InGaAlP), alumimun nitride (AlN), zinc oxide (ZnO), and others, e.g., other semiconductors, polymers, dye doped polymers, organic materials, insulators, glass(es), quartz, or combination of any of these materials.

In the very early days, we understand that one of the first lamps was invented around tens of thousands of years BC. Natural objects including hollow rocks, shells, or the other materials were filled with moss or a similar material that was soaked with animal fat and ignited. Improvements such as wicks were later added to selectively control the rate of burning. Around the 7th century BC, the Greeks began making terra cotta lamps to replace handheld torches. The word lamp is derived from the Greek word lampas, meaning torch.

By the early in the 19th century, much of the cities in the United States had streets that were lighted using gas lamps. Gas lighting for streets gave way to low pressure sodium and high pressure mercury lighting in the 1930s and the development of the electric lighting at the turn of the 19th century replaced gas lighting in homes. A further history of the early lamps can be found at www.about.com. Gas lamps were soon replaced, at least for the most part, with electric lights.

Thomas Edison's was challenged with the development of a practical incandescent electric light. With use of lower current electricity, a small carbonized filament, and an improved vacuum inside the globe, Edison produced a reliable, long-lasting source of light. Although the basic concept of electric lighting was not new, Edison developed one of the first practical home use lights, including basic elements to make the incandescent light practical, safe, and economical. After one and a half years of work, success was achieved when an incandescent lamp with a filament of carbonized sewing thread burned for thirteen and a half hours. Accordingly, incandescent electric light proliferated to use in-homes, outside, and almost any other place.

Other types of lighting such as fluorescent lighting emerged. Fluorescent lighting relies upon excitation of a gaseous species within a vacuum to create luminescence. Many modern office buildings and homes often use various types of fluorescent lighting, which often uses less power and are maintained at lower temperatures than the conventional incandescent electric light. As time progresses, solid state lighting in the form of light emitting diodes, commonly called “LEDs” have emerged.

As merely an example, InGaN quantum wells (QW)-based light emitting diodes have been improved and commercialized as light sources in the ultraviolet and visible spectral regions. See, for example, S. Nakamura, T. Mukai and M. Senoh, “Candela-class high brightness In GaN/AlGaN double-heterostructure blue-light-emitting diodes,” Appl. Phys. Lett. 64, 1687-1689, 1994; S. Nakamura, T. Mukai, M. Senoh and N. Iwase, “High-brightness InGaN/AlGaN double-heterostructure blue-green-light-emitting diodes,” J. Appl. Phys. 76, 8189-8191, 1994; and T. Mukai, M. Yamada, S. Nakamura, “Current and temperature dependences of electroluminescence of InGaN-based UV/blue/green light-emitting diodes,” Jpn. J. Appl. Phys. 37, L1358-L1361, 1998. Moreover, white light LEDs, in which a blue LED is combined with a yellow phosphor, have been commercialized and offer a replacement for conventional incandescent and fluorescent light bulbs. See, S. Nakamura and G. Fasol, The blue laser diode: GaN based light emitting diode and lasers, Springer, Berlin, 1997. However, the promise of inexpensive solid state lighting has so far been delayed by the relatively poor extraction efficiency of light from semiconductor light sources. We believe that the development of efficient and bright white LEDs will rapidly result in commercialization of efficient solid state illumination sources. A desirable requirement for a competitive LED for solid state lighting is the development of new methods to increase its quantum efficiency of light emission.

From the above, it is seen that improved light emitting diode structures and methods of manufacture are desired.

### BRIEF SUMMARY OF THE INVENTION

According to the present invention, techniques for emission of electromagnetic radiation using light emitting diodes and their methods of manufacture are provided. More particularly, the present invention provides a method and structure for a light emitting diode having enhanced characteristics by surface plasmon coupling. Merely by way of example, the invention has been applied to indium gallium nitride (“InGaN”) quantum wells, but it would be recognized that the invention has a much broader range of applicability. For example, the invention can be applied to other semiconductor materials such as silicon (Si), germanium (Ge), silicon carbide (SiC), gallium nitride (GaN), indium gallium nitride (InGaN), aluminum gallium nitride (AlGaN), zinc selenium (ZnSe), zinc cadminum selenium (ZnCdSe), gallium arsenide (GaAs), aluminum gallium arsenide (AlGaAs), indium gallium srdenide (InGaN), gallium phosphide (GaP), indium gallium aluminum phosphide (InGaAlP), alumimun nitride (AlN), zinc oxide (ZnO), and others, e.g., other semiconductors, polymers, dye doped polymers, organic materials, insulators, glass(es), quartz, or combination of any of these materials.

In a specific embodiment, the present invention provides a light emitting semiconductor device, e.g., light emitting diode (i.e., LED), laser. The device has a substrate (e.g., transparent) comprising a surface region in a certain embodiment. In a specific embodiment, the term “substrate” can include multi-layer structures including semiconductor materials. In alternative embodiments, which have been described, the term substrate can be for bulk materials. The device has a first type semiconductor material overlying the surface region of the substrate. A quantum well material (e.g., active region) is overlying the semiconductor material. A second type semiconductor material is overlying the quantum well material. The device has a metal layer overlying the second type semiconductor material and a surface region on the metal layer. In a preferred embodiment, the device has a spatial spacing (e.g., distance) between the metal layer and the quantum well material to cause a coupling between a surface plasmon mode at the surface region of the metal layer and the quantum well material. The device has a textured interface region between the metal layer and the second type of semiconductor material to enhance formation of electromagetic radiation from the surface plasmon mode. The coupling causes an increase of a level of the electromagnetic radiation to be derived from the quantum well material. Here, the terms “first” and “second” are not intended to be limiting but merely for illustrative purposes only. Additionally, the term “overlying” or even “underlying” is not intended to be limited or be used as a reference with a gravitational force or other fixed reference plane, although such term may be used for such reference depending upon the embodiment.

In an alternative specific embodiment, the present invention provides a method for fabricating light emitting devices. The method includes providing a substrate comprising a surface region. The method includes forming a first type semiconductor material overlying the surface region of the substrate and forming a quantum well material (e.g., active region) overlying the semiconductor material. The method forms a second type semiconductor material overlying the quantum well material. A textured interface region is formed between the second type semiconductor material and a metal layer to be formed overlying the second type semiconductor material. Depending upon the embodiment, the textured interface is provided on either the semiconductor material and/or the metal layer. The method includes forming a metal layer including a surface region overlying the second type semiconductor material at a preferred spatial spacing between the surface region and the second type semiconductor material. The preferred spacing is sufficient to cause a coupling between a surface plasmon mode at the surface region of the metal layer and the quantum well material. The textured interface region enhances formation of a first electromagnetic radiation to be derived from the surface plasmon mode. Additionally, the coupling associated with the spatial spacing between the surface region of the metal layer and the second type semiconductor material causes an increase of a level of second electromagnetic radiation to be derived from the quantum well material.

In an alternative specific embodiment, the invention provides another light emitting semiconductor device. The device has a substrate (including a semiconductor region or active region) comprising a surface region and a metal layer overlying the surface region of the substrate. The device has an interface region between the surface region and the metal layer and a textured characteristic at the interface region. A spatial spacing is formed between the metal layer and the substrate to cause a coupling between electron-hole pairs generated in the substrate and a surface plasmon mode at the interface region.

In a further specific embodiment, the invention provides still another light emitting semiconductor device. The device has a first substrate comprising a first surface region. A first metal layer is formed overlying the first surface region of the first substrate. A first interface region is formed between the first surface region and the first metal layer. The device has a first textured characteristic at the first interface region. The device has a first spatial spacing between the first metal layer and the first substrate to cause a coupling between electron-hole pairs generated in the first substrate and a surface plasmon mode at the first interface region. The device also has another sequence of substantially repeating elements according to a specific embodiment. The device has a second substrate comprising a second surface region and a second metal layer overlying the second surface region of the second substrate. The device has a second interface region between the second surface region and the second metal layer and a second textured characteristic at the second interface region. The device also has a second spatial spacing between the second metal layer and the second substrate to cause a coupling between electron-hole pairs generated in the second substrate and a surface plasmon mode at the second interface region. Depending upon the embodiment, the device can also have an Nth set of elements, where N is greater than 2, to form an array configuration in either horizontal or vertical stacking configuration. In a specific embodiment, the term “substrate” can include multi-layer structures including semiconductor materials. In alternative embodiments, which have been described, the term substrate can be for bulk materials.

Still further, the present invention provides a method for manufacturing light emitting semiconductor devices. The method includes providing a substrate comprising a surface region and forming a metal layer overlying the surface region of the substrate. In a specific embodiment, the metal layer and the surface region are characterized by a spatial spacing between the metal layer and the substrate to cause a coupling between electron-hole pairs generated in the substrate and a surface plasmon mode at an interface region between the metal layer and the surface region. Additionally, the interface region has a textured characteristic between the surface region and the metal layer. The textured characteristics causes emission of electromagnetic radiation through the surface plasmon mode or like mechanism according to a specific embodiment.

Moreover, the present invention provides yet another a light emitting semiconductor device. The device has a substrate comprising a surface region and a metal layer overlying the surface region of the substrate. The device has an interface region between the surface region and the metal layer. A textured characteristic is provided at or within a vicinity of the interface region. The device has a spatial spacing between the metal layer and the substrate to cause a coupling between electron-hole pairs generated in the substrate and a surface plasmon mode at the interface region. In a preferred embodiment, the device has a first electrode coupled to the substrate and a second electrode coupled to the metal layer. A voltage source is coupled between the first electrode and the second electrode to generate electromagnetic radiation in the substrate. Preferably, the electromagnetic radiation has been enhanced by the coupling between the electron-hole pairs generated by the substrate and the surface plasmon mode at the interface region.

In a specific embodiment, certain various to any of the above embodiments may exist. For example, n-type and p-type materials can be interchanged for the first and second semiconductor materials. Additionally, the term “substrate” is not used herein to mean a specific structure but is used as a general term. The substrate can be a single material, a multiple layered material, including active region, and other types of materials, which are homogeneous or hetero-structures or any combination of these. Additionally, the term “spatial spacing” is not to be unduly limiting to any of the embodiments herein and is not specifically limited to the thickness of the second semiconductor layer except for certain embodiments. Of course, there can be other variations, modifications, and alternatives.

Numerous benefits can be achieved using the present invention over conventional techniques. As merely an example, the present invention can provide enhanced emission efficiencies using a surface plasmon coupling effect or like influences that leads to enhancement of electromagnetic radiation emitted from the light emitting device structure. Additionally, the invention can be implemented using conventional materials and process technology. In preferred embodiments, the invention including method and structure can be used with certain conventional light emitting diode structures. In other preferred embodiments, the present method and structures may lead to solid state light sources, which would replace conventional light sources such as fluorescent tubes, light bulbs, etc. Moreover, the present invention including method and device can lead to enhanced emission rates according to certain embodiments. Such enhanced rates may be useful for high speed light emitters for communication applications, optical coupling applications, and others. The present manufacturing technique can also lead to improved throughput, efficiency, and yield. Depending upon the embodiment, one or more of these benefits may be achieved. These and other benefits are described throughout the present specification and more particularly below.

From the above, it is seen that techniques for improving ways to manufacture light emitting diode devices are highly desired.

### BRIEF DESCRIPTION OF THE DRAWINGS

FIG. 1 is a simplified cross-sectional-view diagram of a light emitting device according to an embodiment of the present invention;

FIG. 1A is a simplified cross-sectional view diagram illustrating an interface region of the light emitting device according to an embodiment of the present invention;

FIG. 2 is a plot of intensity against wavelength for a light emitting device according to an embodiment of the present invention;

FIG. 3 is a simplified cross-sectional-view diagram of a light emitting device according to an alternative embodiment of the present invention;

FIG. 4 illustrates various light emitting device structures according to alternative embodiments of the present invention;

FIGS. 4A, 4B, and 4C illustrates various light emitting device structures according to yet alternative embodiments of the present invention;

FIG. 5 is a historical plot of luminescence efficiency against a time frequency;

FIG. 6 is a simplified flow diagram of a method of manufacturing a light emitting device structure according to an embodiment of the present invention;

FIG. 7 illustrates various structures for forming a textured characteristic in light emitting devices according to embodiments of the present invention;

FIGS. 8 through 13 illustrate various electrical pumped light emitting devices according to embodiments of the present invention; and

FIGS. 14 through 23 illustrate simplified diagrams associated with experimental results associated with the present light emitting devices according to embodiments of the present invention.

### DETAILED DESCRIPTION OF THE INVENTION

According to the present invention, techniques for emission of electromagnetic radiation using light emitting diodes and their methods of manufacture are provided. More particularly, the present invention provides a method and structure for a light emitting diode having enhanced characteristics by surface plasmon coupling. Merely by way of example, the invention has been applied to indium gallium nitride (“InGaN”) quantum wells, but it would be recognized that the invention has a much broader range of applicability. For example, the invention can be applied to other semiconductor materials such as silicon (Si), germanium (Ge), silicon carbide (SiC), gallium nitride (GaN), indium gallium nitride (InGaN), aluminum gallium nitride (AlGaN), zinc selenium (ZnSe), zinc cadminum selenium (ZnCdSe), gallium arsenide (GaAs), aluminum gallium arsenide (AlGaAs), indium gallium srdenide (InGaN), gallium phosphide (GaP), indium gallium aluminum phosphide (InGaAlP), alumimun nitride (AlN), zinc oxide (ZnO), and others, e.g., other semiconductors, polymers, dye doped polymers, organic materials, insulators, glass(es), quartz, or combination of any of these materials.

In a specific embodiment, the present invention provides light emitting devices, which emission efficiencies were enhanced by the surface plasmon (SP) coupling, and certain methods of manfuacture. Surface plasmons can increase the density of states and the spontaneous emission rate in the light emitting materials. So far, the actual enhancement of light emission by surface plasmon coupling has not been observed directly for visible light. More recently, we have measured a seventeen-fold increase or at least a seventeen-fold in the photoluminescence intensity along with a seven-fold increase or at least a seven-fold increase in the internal quantum efficiency of InGaN QW (ηᵢₙₜ) of InGaN/GaN quantum well (QW) when these are in close proximity to silver layers. This metallization technique is expected to be applicable to the improvement of most light emitting diodes (LEDs) according to a specific embodiment.

In alternative specific embodiments, the present invention also provides devices and methods of manufacture using similar surface plasmon enhanced light emission from SiO/SiO₂ super lattice structures and dye-molecules doped polymer materials, and electron conjugated polymer materials. We propose the design and fabrication of the super bright LEDs based on this surface plasmon coupling according to preferred embodiments. We believe that such super bright LEDs will enable the rapid development of solid-state light sources so that these can replace conventional light sources such as fluorescent tubes or light bulbs also in preferred embodiments. As the predicted market of solid lighting is expected to exceed 10 billion dollars, the proposed devices will have a large impact, which may be a benefit associated with the present inventions.

Certain conventional bright white light-emitting diodes (LED) based on InGaN (or ZnCdSe, etc.) quantum wells (QWs) or organic light-emitting diodes (OLED) have been developed and are expected to eventually replace more traditional fluorescent and incandescent tubes as illumination sources. However, the original promise of a solid state “illumination revolution” has so far been delayed as the light emission efficiencies of these new sources have been somewhat limited. An most important desire for a competitive LED or OLED source for solid-state lighting is the development of methods to increase its overall quantum efficiency of emission.

More recently, we reported large photoluminescence (PL) increases from InGaN/GaN QW material coated with metal layers (Natute Materilas, 3,601,2004). By polishing the bottom surface of grown InGaN samples, QW emission can be photo-excited and measured through the back of the substrate, permitting the rapid comparison between photoluminescence (“PL”) from QWs in proximity with different metal coatings and distance to the metal film as illustrated by FIG. 1, which is a simplified cross-sectional view diagram 100. Such diagram is merely an illustration and should not unduly limit the scope of the claims herein. One of ordinary skill in the art would recognize many variations, modifications, and alternatives. As shown, the diagram 100 includes a substrate 101. The substrate is preferably an optically transparent material. Such optically transparent material can be selected from quartz, silicon, glass, or sapphire, any combination of these, and other suitable materials. The substrate has a certain thickness and surface region 103, which will be an interface with an overlying layer. The substrate also includes a backside region, which has been polished and is suitable for optical devices. Certain substrates can be removed to form more advanced light emitting devices and the like.

Overlying the substrate is a first semiconductor layer 105. The first semiconductor layer is made of an n-type semiconductor material. The n-type semiconductor material can include a single material, multiple materials, and others. As merely an example, the semiconductor material can be made of any one or possibly combinations of silicon (Si), germanium (Ge), silicon carbide (SiC), gallium nitride (GaN), indium gallium nitride (InGaN), aluminum gallium nitride (AlGaN), zinc selenium (ZnSe), zinc cadminum selenium (ZnCdSe), gallium arsenide (GaAs), aluminum gallium arsenide (AlGaAs), indium gallium srdenide (InGaN), gallium phosphide (GaP), indium gallium aluminum phosphide (InGaAlP), alumimun nitride (AlN), zinc oxide (ZnO), and others, e.g., other semiconductors, polymers, dye doped polymers, organic materials, insulators, glass(es), quartz, or combination of any of these materials. Overlying the n-type semiconductor layer is a quantum well region 107, which has a suitable thickness and characteristic.

In a preferred embodiment, the quantum well comprises an InGaN material of suitable thickness and other characteristics. InGaN quantum well is grown onto GaN/sapphire substrates according to a specific embodiment. The InGaN quantum well has a thickness of 3 nanometers and 10 nanometer thick GaN is grown onto the quantum well according to a specific embodiment. Of course, one of ordinary skill in the art would recognize other variations, modifications, and alternatives.

In a specific embodiment, the device also has a second semiconductor layer 109 overlying the quantum well. The second semiconductor layer is made of a p-type semiconductor material. The p-type semiconductor material can include a single material, multiple materials, and others. As merely an example, the semiconductor material can be made of any one or possibly combinations of silicon (Si), germanium (Ge), silicon carbide (SiC), gallium nitride (GaN), indium gallium nitride (InGaN), aluminum gallium nitride (AlGaN), zinc selenium (ZnSe), zinc cadminum selenium (ZnCdSe), gallium arsenide (GaAs), aluminum gallium arsenide (AlGaAs), indium gallium srdenide (InGaN), gallium phosphide (GaP), indium gallium aluminum phosphide (InGaAlP), alumimun nitride (AlN), zinc oxide (ZnO), and others, e.g., other semiconductors, polymers, dye doped polymers, organic materials, insulators, glass(es), quartz, or combination of any of these materials.

The device also has a metal film 111 formed over the second semiconductor layer. The metal film may be a single metal film or multiple metal films, which are coupled to each other, according to a specific embodiment. As merely an example, the metal film can be made of a material such as gold, silver, aluminum, titanium, tungsten, copper, platinum, chromium, palladium, any practical combination of these, and the like. The metal film can also be made of various alloys, and other combinations of these metals, and other materials. Depending upon the embodiment, each metal has a value of a surface plasmon frequency. Preferably, the metal, which has the surface plasmon frequency, matches and/or is associated with an emission wavelength selected to enhance the emission, according to a specific embodiment. As shown, the metal film covers a portion of the second semiconductor layer to block such portion, while maintaining other portions 109 free from the metal layer. Of course, one of ordinary skill in the art would recognize other variations, modifications, and alternatives. Further details of certain features of the light emitting device according to a specific embodiment can be found throughout the present specification and more particularly below.

FIG. 1A is a simplified cross-sectional view diagram illustrating an interface region of the light emitting device according to an embodiment of the present invention. This diagram is merely an illustration and should not unduly limit the scope of the claims herein. One of ordinary skill in the art would recognize many variations, modifications, and alternatives. Like reference numerals are used in FIG. 1A, as the prior Figure, for illustrative purposes only, without unduly limiting the scope of the claims herein. As shown, the light emitting device includes a first semiconductor layer 105, an overlying quantum well layer 107, an overlying second semiconductor layer 109. A metal layer 111 is formed overlying the second semiconductor layer. The metal layer and the second semiconductor layer include an interface region 151. In a preferred embodiment, the device has a textured interface region between the metal layer and the second type of semiconductor material to enhance formation of electromagetic radiation from the surface plasmon mode. That is, energy provided on the metal layer leads to emission of electromagnetic radiation in the form of light (e.g., hω_{SP}) according to a preferred embodiment. The textured region is characterized to cause the emission of light, rather than have the energy be outputted as thermal energy, according to a specific embodiment. Other mechanisms can also be used depending upon the embodiment. In certain embodiments, the surface plasmon is at a surface plasmon resonance frequency or state to provide a predetermined (e.g., maximum) level of electromagnetic radiation via the interface between the metal and the semiconductor material. In a specific embodiment, the textured surface is characterized by a size and certain shape of the textured surface. In a specific embodiment, the size of the texture is characterized by a few tens or few hundred nano meter scale to tune the localized surface plasmon frequency. Possible variations of the textures are random roughness, grating, hole array, pillar array, etc. (fabricated by lithography and etching) can also be included. Of course, there can be other variations, modifications, and alternatives.

In a preferred embodiment, the device also has a spatial spacing (e.g., distance) 10 nanometers between the metal layer and the quantum well material, although other dimensions can also be used. Such distance is preferably very short within a near field region (shorter than for example 50 nanometers and/or even about a vicinity of zero in certain embodiments) because of the surface plasmon mode is an evanescent wave according to a certain embodiment. In preferred embodiments, the spatial spacing is adequate to cause a coupling between a surface plasmon mode at the surface region of the metal layer and the quantum well material. The coupling causes an increase of a level of the electromagnetic radiation to be derived from the quantum well material. Here, the surface plasmon coupling may be defined as coupling rate k_{SP}. The coupling between the quantum well and the surface plasmon increases an emission of a level of the electromagnetic radiation according to preferred embodiments. Such increase in electromagnetic radiation has been described throughout the present specification and more particularly below.

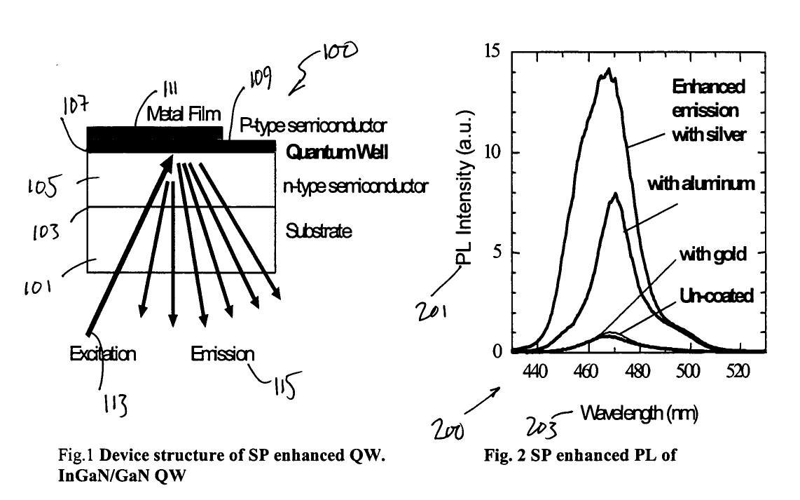

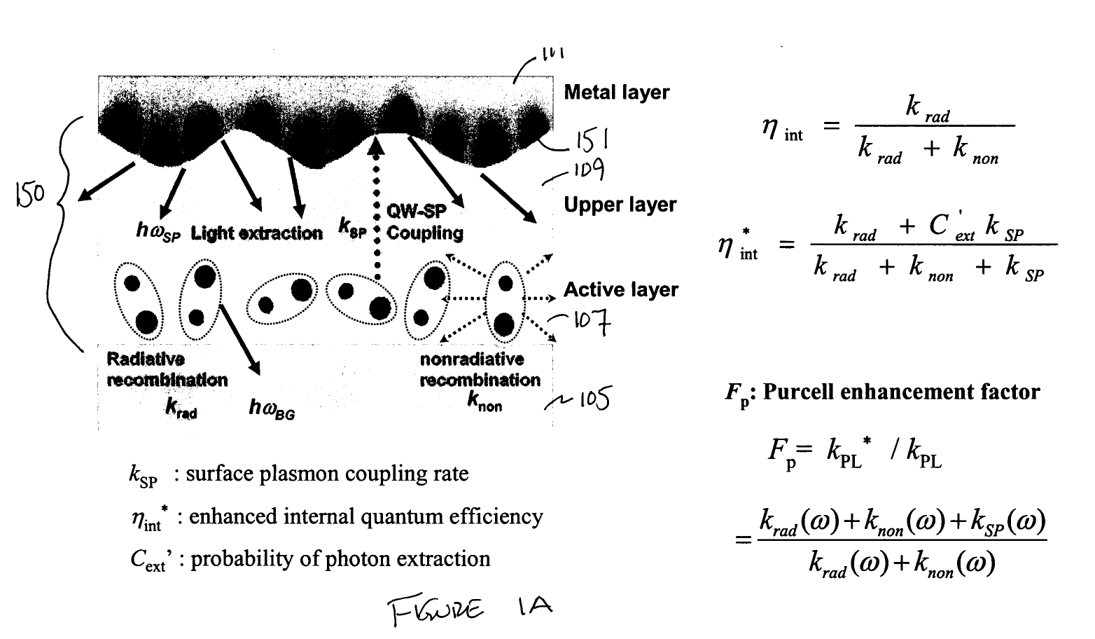

As illustrating in a plot 200 of FIG. 2, we observed a fourteen-fold peak intensity and seventeen-fold integrated intensity increase in the PL intensity for silver metal layer samples along with a seven-fold increase for aluminum metal layer samples in the internal quantum efficiency (ηᵢₙₜ) of InGaN QW. As shown, the plot includes a PL intensity 201 along a vertical axis, which intersects wavelength in nanometers, along a horizontal axis. The plot includes four sets of data, including (1) enhanced emission with silver metal; (2) enhanced emission with aluminum metal; (3) emission with gold metal; and (4) an uncoated device sample. As shown, no such enhancements were obtained from samples coated with gold, as its well-known surface plasmon resonance occurs only at longer wavelengths.

Moreover, the present device and methods include similar light emission enhancements obtained for silicon-based super-lattice structures and organic dyes doped into polymer hosts. Therefore, we expect surface plasmon assisted light emission to lead to a class of very bright (e.g., greater than conventional lamp bulbs and fluorescent tubes) and high-speed solid-state light sources that offer a realistic alternative to conventional light sources. This technique should be available be available for other light emitting materials, for example, other wide-bandgap semiconductors (e.g., AlInGaP (yellow), ZnCdSe (green), ZnO (blue), AlN (UV)) or several OLED materials for wide wavelength regions.

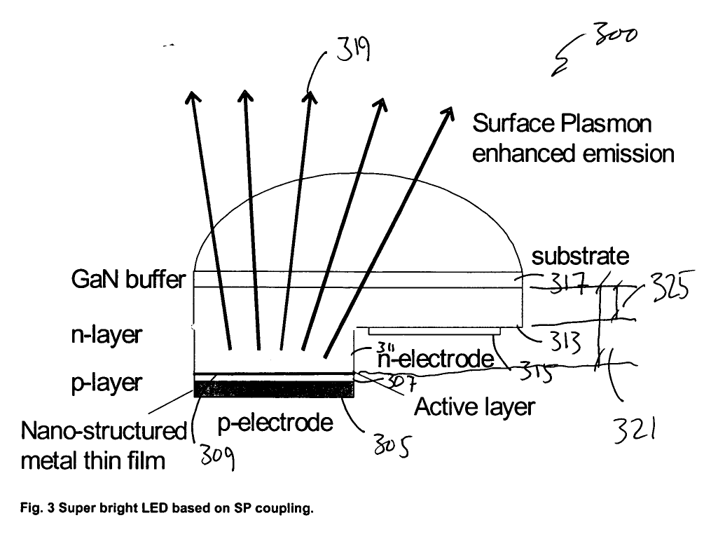

We propose to fabricate the electrical pumped super bright LED structures by using the surface plasmon-QW coupling, as illustrated in a simplified cross-sectional view diagram 300 of FIG. 3. This diagram is merely an illustration and should not unduly limit the scope of the claims herein. One of ordinary skill in the art would recognize many variations, modifications, and alternatives. In order to design even more efficient structures and to fabricate electrical pumped LED devices by using surface plasmon coupling, we have to understand and optimize both mechanism and dynamics of energy transfer and light extraction. We already found that the metal nanostructure is very important fact to decide the light extraction and localized surface plasmon frequency. As shown, the device includes a substrate with various layers. The substrate includes a GaN buffer layer 317 and an overlying n-type semiconductor layer 313. The n-type semiconductor layer includes a first thickness 325 and a second thickness 321. Here, the terms “first” and “second” are not intended to be limiting but merely for illustrative purposes only. In a preferred embodiment, the n-type semiconductor layer is magnesium doped gallium nitride (p-GaN:Mg), but can also be other materials.

As shown, the first thickness of n-type material includes an n-type electrode 315, which is coupled to the first thickness of material. As merely an example, the n-type electrode is titanium/aluminum, although other materials can be used, depending upon the embodiment. In the second thickness of material 311, the device includes an overlying quantum well layer (i.e., active layer) 309, and an overlying p-type layer 307. Preferably, the quantum well layer is indium gallium nitride (InGaN) and the p-type layer is silicon doped gallium nitride (N—GaN:Si). The device includes an overlying metal layer 305, which may be a variety of suitable materials. In a preferred embodiment, the metal layer is silver or silver bearing material. The metal layer can also serve as an electrode, as shown. Certain embodiments of the device can be found throughout the present specification and more particularly below.

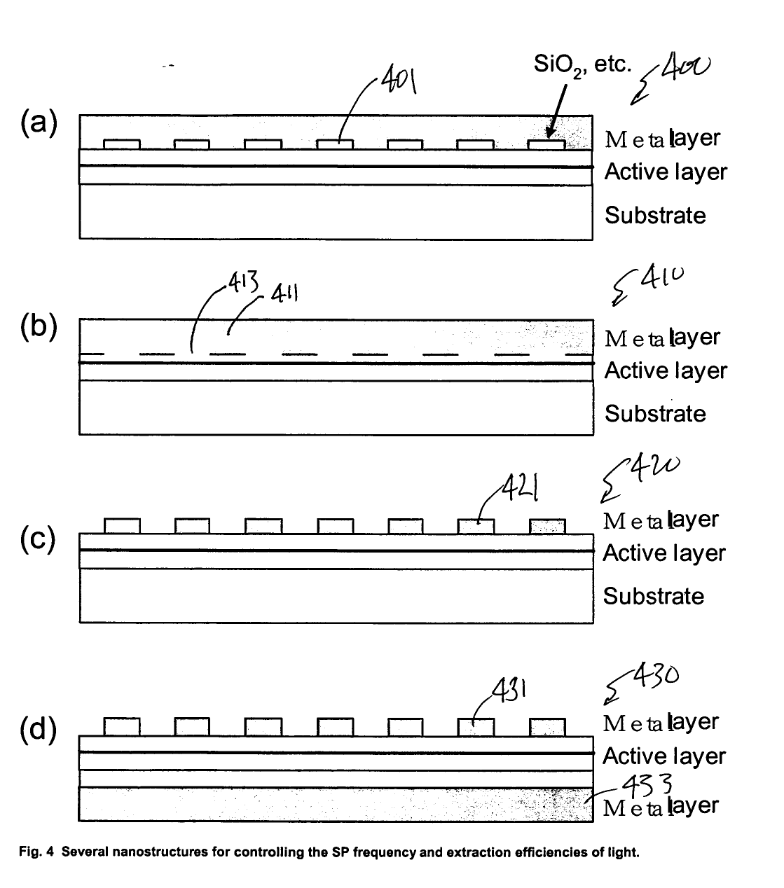

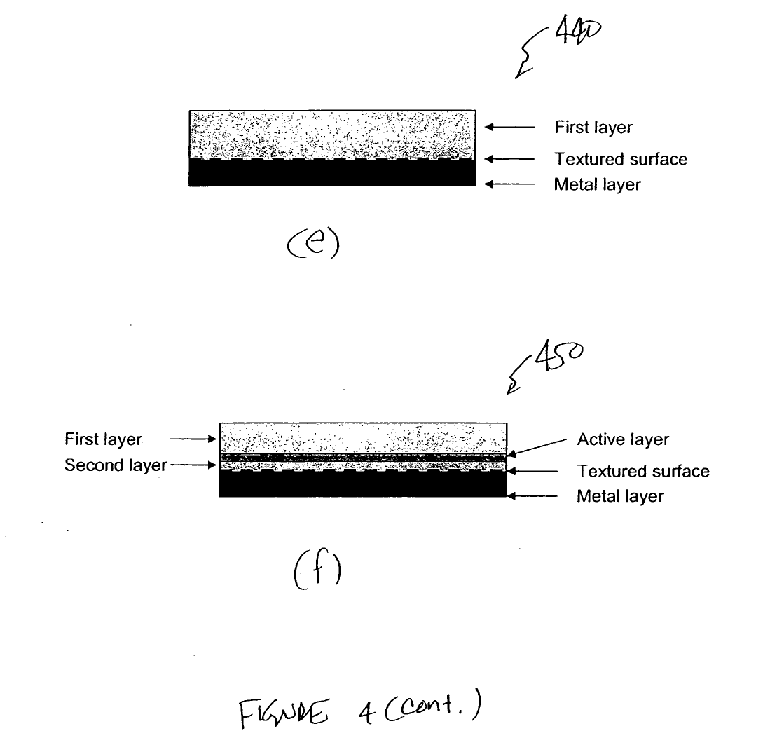

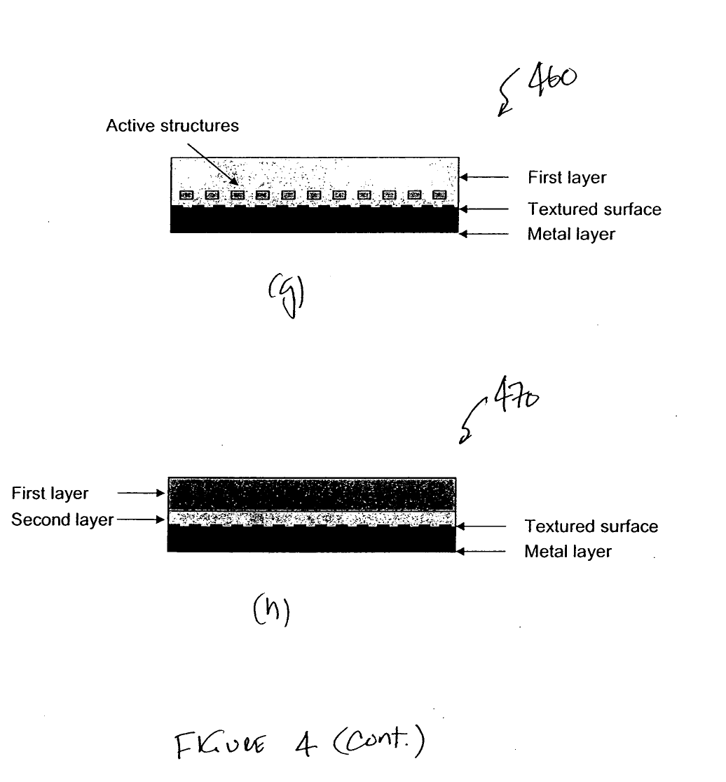

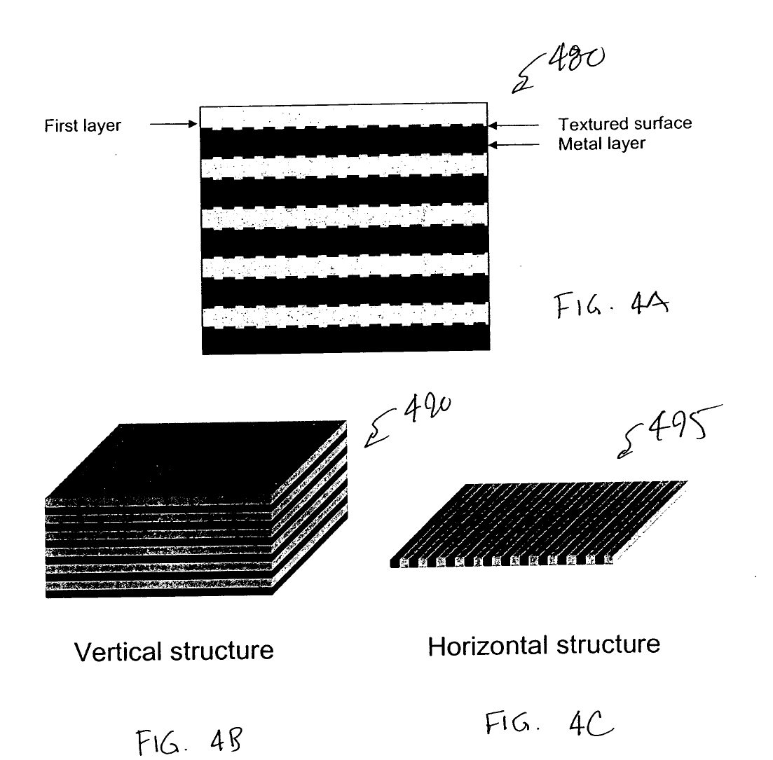

FIG. 4 illustrates various light emitting device structures 410, 420, 430, 440, 450, 460, 470 according to alternative embodiments of the present invention. This diagram is merely an illustration and should not unduly limit the scope of the claims herein. One of ordinary skill in the art would recognize many variations, modifications, and alternatives. As shown in the various diagrams, certain layers including substrate, active layer, metal layer, and textured surfaces are shown. Other features such as a plurality of insulating structures 401 (separated from each other) (e.g., SiO₂) within the metal layer of device structure 410 are shown. Additionally, a textured or patterned metal layer 411, which includes portions 413 of semiconductor material, is also shown in the device 410 of FIG. 4. The device structure 420 can also include a plurality of metal patterns 421, which are disposed on the semiconductor layer. Each of the metal patterns can be a line or other suitable spatial configuration. In a specific embodiment, the device structure 430 can include a plurality of metal lines 431, a substrate, an active layer, a first semiconductor layer, a second semiconductor layer, and a backside metal layer 433. Other device structures 440, 450, 460, and 470 are also illustrated in FIG. 4.

FIGS. 4A, 4B, and 4C illustrates various light emitting device structures according to yet alternative embodiments of the present invention. These diagrams are merely illustrations and should not unduly limit the scope of the claims herein. One of ordinary skill in the art would recognize many variations, modifications, and alternatives. As shown, the device 480 has a first substrate comprising a first surface region. A first metal layer is formed overlying the first surface region of the first substrate. A first interface region is formed between the first surface region and the first metal layer. The device has a first textured characteristic at the first interface region. The device has a first spatial spacing between the first metal layer and the first substrate to cause a coupling between electron-hole pairs generated in the first substrate and a surface plasmon mode at the first interface region. In this embodiment, the substrate includes multiple layers, including a semiconductor layer, to generate electron hole pairs. Of course depending upon the embodiment, the term substrate can have other meanings, as well.

As also shown, the device also has another sequence of substantially repeating elements according to a specific embodiment, as shown in FIG. 4A. The device has a second substrate comprising a second surface region and a second metal layer overlying the second surface region of the second substrate. The device has a second interface region between the second surface region and the second metal layer and a second textured characteristic at the second interface region. The device also has a second spatial spacing between the second metal layer and the second substrate to cause a coupling between electron-hole pairs generated in the second substrate and a surface plasmon mode at the second interface region. Depending upon the embodiment, the device can also have an Nth set of elements, where N is greater than 2, to form an array configuration in either horizontal 495 or vertical 490 stacking configuration, as illustrated by FIGS. 4B and 4C, for example.

We fabricate nanostructured metal layers to explore the dependence of the plasmon enhancement on metal composition, thickness and grain shapes and sizes. Until now, a lot of efforts to increase the emission efficiency have been investigated based on the development of the crystal growth techniques, but, there are limited. Our surface plasmon-QW coupling method is one solution to increase dramatically the efficiencies of LEDs. Of course, there can be other variations, modifications, and alternatives.

As noted above, we obtained a seven-fold increase in the ηᵢₙₜ of InGaN QW. The seven-fold increasing of ηᵢₙₜ means that seven-fold improvement of the efficiency of electrically pumped LED devices should be achievable because ηᵢₙₜ is a desired property, which may not depend on the pumping method, such as light and/or electrical. In a preferred embodiment, such improved efficiencies of the white LEDs, in which a blue LED is combined with a yellow phosphor, are desired to be larger than those of conventional fluorescent lamps and/or conventional light bulbs, which will be further explained below.

FIG. 5 shows the historical development of solid-state light emitters as will be useful for a foundation for the present devices and methods of manufacture. The luminous efficacy of commercial white LEDs is 25 lm/W at a current of 20 mA at room temperature. This value is still lower than the 75 lm/W efficacy of fluorescent tubes.

Over 3-fold improvements are desired for LEDs to exceed the current fluorescent lamps or light bulbs. The highest ηᵢₙₜ values of commercialized InGaN LEDs are around 50%. By optimizing QW-SP coupling, ηᵢₙₜ values of almost 100% are achievable. We estimate that at least 2-fold increases of ηᵢₙₜ and over 2-fold increases of light extraction efficiency can be obtained from the present best InGaN LEDs. Therefore, the proposed surface plasmon-LEDs are expected to achieve high efficiencies of 1201 m/W, much beyond those measured in fluorescent tubes (751 m/W). Such super bright LED performance could fuel the rapid development of solid-state light sources and replace fluorescent tubes or light bulb with solid state sources. Further details of methods of manufacturing the present light emitting device can be found throughout the present specification and more particularly below.

A method for fabricating a light emitting device according to an embodiment of the present invention may be outlined as follows.
1. Provide a substrate (e.g., transparent) comprising a surface region;
2. Optionally, form an electrode onto a backside of the substrate;
3. Form a first type semiconductor material overlying the surface region of the substrate;
4. Form a quantum well material overlying the semiconductor material;
5. Form a second type semiconductor material overlying the quantum well material;
6. Form a textured interface region between the second type semiconductor material and a metal layer to be formed overlying the second type semiconductor material with a certain characteristic to enhance a plasmon resonance effect at the interface region between the metal layer and the second type semiconductor material;
7. Form a metal layer including a surface region overlying the second type semiconductor material at a preferred spatial spacing between the surface region and the second type semiconductor material sufficient to cause a coupling between a surface plasmon mode at the surface region of the metal layer and the quantum well material;
8. Form an electrode overlying the metal layer; and
9. Perform other steps, as desired.

The above sequence of steps provides a method for manufacturing light emitting devices according to an embodiment of the present invention. As shown, the method uses a combination of steps including a way of forming a textured surface (or other like surface having characteristics to enhance a surface plasmon mode, which may be a resonance effect, to generate electromagnetic radiation) and a spatial spacing to enhance coupling between the metal layer and quantum well layer according to a preferred embodiment of the present invention. Other alternatives can also be provided where steps are added, one or more steps are removed, or one or more steps are provided in a different sequence without departing from the scope of the claims herein. Further details of the present method can be found throughout the present specification and more particularly below.

FIG. 6 is a simplified flow diagram 600 of a method of manufacturing a light emitting device structure according to an embodiment of the present invention. This flow diagram is merely an illustration and should not unduly limit the scope of the claims herein. One of ordinary skill in the art would recognize many variations, modifications, and alternatives. FIG. 7 illustrates various structures for forming a textured characteristic in light emitting devices according to embodiments of the present invention. This diagram merely illustrates examples, which should not unduly limit the scope of the claims herein. One of ordinary skill in the art would recognize many variations, alternatives, and modifications. As shown, the flow diagram begins at start, step 601. The method includes providing a substrate (step 603) comprising a surface region. The substrate is preferably an optically transparent material. Such optically transparent material can be selected from quartz, silicon, glass, or sapphire, any combination of these, and other suitable materials. The substrate has a certain thickness and surface region, which will be an interface with an overlying layer. The substrate also includes a backside region, which has been polished and is suitable for optical devices.

The method includes forming a first type semiconductor material (step 605) overlying the surface region of the substrate. The first semiconductor layer is made of an n-type semiconductor material. The n-type semiconductor material can include a single material, multiple materials, and others. As merely an example, the semiconductor material can be made of any one or possibly combinations of silicon (Si), germanium (Ge), silicon carbide (SiC), gallium nitride (GaN), indium gallium nitride (InGaN), aluminum gallium nitride (AlGaN), zinc selenium (ZnSe), zinc cadminum selenium (ZnCdSe), gallium arsenide (GaAs), aluminum gallium arsenide (AlGaAs), indium gallium srdenide (InGaN), gallium phosphide (GaP), indium gallium aluminum phosphide (InGaAlP), alumimun nitride (AlN), zinc oxide (ZnO), and others, e.g., other semiconductors, polymers, dye doped polymers, organic materials, insulators, glass(es), quartz, or combination of any of these materials.

As shown, the method includes forming a quantum well material (step 607) overlying the semiconductor material. In a preferred embodiment, the quantum well comprises an InGaN material of suitable thickness and other characteristics. InGaN quantum well is grown onto GaN/sapphire substrate and the InGaN quantum well has a thickness of about 3 nanometers according to a specific embodiment. A 10 nanometer thick GaN is grown onto the quantum well according to the specific embodiment. Of course, one of ordinary skill in the art would recognize other variations, modifications, and alternatives.

The method forms a second type semiconductor material (step 609) overlying the quantum well material. The second semiconductor layer is made of a p-type semiconductor material. The p-type semiconductor material can include a single material, multiple materials, and others. As merely an example, the semiconductor material can be made of any one or possibly combinations of silicon (Si), germanium (Ge), silicon carbide (SiC), gallium nitride (GaN), indium gallium nitride (InGaN), aluminum gallium nitride (AlGaN), zinc selenium (ZnSe), zinc cadminum selenium (ZnCdSe), gallium arsenide (GaAs), aluminum gallium arsenide (AlGaAs), indium gallium srdenide (InGaN), gallium phosphide (GaP), indium gallium aluminum phosphide (InGaAlP), alumimun nitride (AlN), zinc oxide (ZnO), and others, e.g., other semiconductors, polymers, dye doped polymers, organic materials, insulators, glass(es), quartz, or combination of any of these materials.

As also shown, a textured interface region is formed (step 611) between the second type semiconductor material and a metal layer to be formed overlying the second type semiconductor material. Depending upon the embodiment, the textured interface is provided on either the semiconductor material and/or the metal layer. Referring now to FIG. 7, various device structures 700, 710, 720, and 730 are illustrated. Such device structures illustrate various methods and resulting structures of forming the textured interface region. The textured interface region can be formed using a rough or textured metal using a certain metal deposition process, as illustrated in the device structure 700. Alternatively, the textured interface can be formed using a plurality of metal nanostructures, e.g., grating, hole array, pillar array, of the metal layer illustrated in the device structure 710. Alternatively, the textured interface can be formed using a plurality of nanostructures formed in the semiconductor layer, as illustrated in the device structure 720. Alternatively, the device structure 730 includes a textured interface region includes a plurality of nanostructures formed on either or both the metal layer or the semiconductor layer. Such nanostructures may be made of a dielectric material or other types of suitable materials, depending upon the embodiment of the present invention. Of course, the textured interface can include any combination of the above, as well as other variations, where the textured material is within the vicinity of the interface and not directly on the interface according to a specific embodiment of the present invention.

The metal film may be a single metal film or multiple metal films, which are coupled to each other, according to a specific embodiment. As merely an example, the metal film can be made of a material such as gold, silver, aluminum, titanium, tungsten, copper, platinum, chromium, and palladium, and the like. The metal film can also be made of various alloys, and other combinations of these metals, and other materials. Of course, one of ordinary skill in the art would recognize other variations, modifications, and alternatives.

The method includes forming the metal layer (step 613) including a surface region overlying the second type semiconductor material at a preferred spatial spacing between the surface region and the second type semiconductor material. The preferred spacing is sufficient to cause a coupling between a surface plasmon mode at the surface region of the metal layer and the quantum well material. The textured interface region enhances formation of a first electromagnetic radiation to be derived from the surface plasmon mode. Additionally, the coupling associated with the spatial spacing between the surface region of the metal layer and the second type semiconductor material causes an increase of a level of second electromagnetic radiation to be derived from the quantum well material. As shown, the method stops, steps 615.

The above sequence of steps provides a method for manufacturing light emitting devices according to an embodiment of the present invention. As shown, the method uses a combination of steps including a way of forming a textured surface (or other like surface having characteristics to enhance a surface plasmon mode, which may be a resonance effect, to generate electromagnetic radiation) and a spatial spacing to enhance coupling between the metal layer and quantum well layer according to a preferred embodiment of the present invention. Other alternatives can also be provided where steps are added, one or more steps are removed, or one or more steps are provided in a different sequence without departing from the scope of the claims herein. Certain device structures and methods of manufacture for electrical pumping devices can be found throughout the present specification and more particularly below.

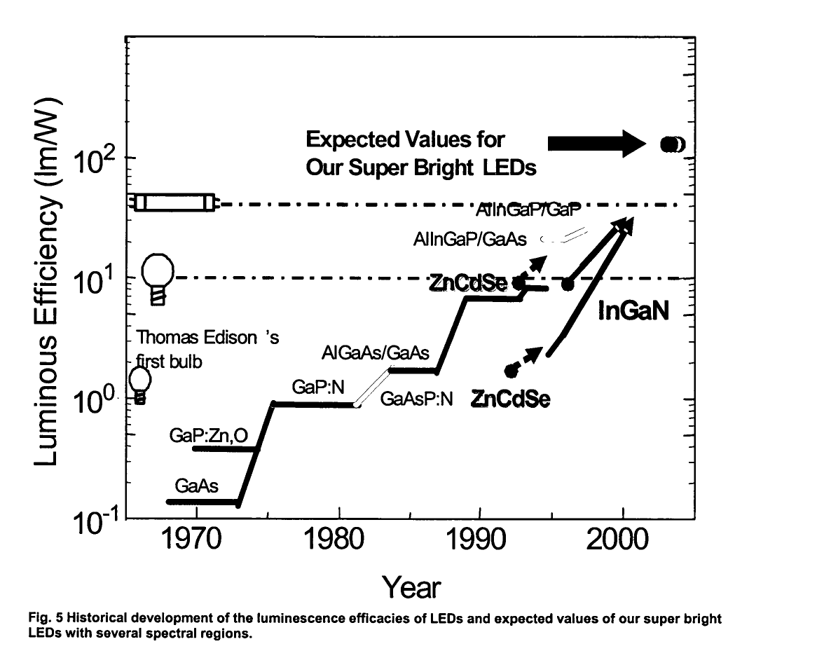

FIGS. 8 through 13 illustrate various electrical pumped light emitting devices according to embodiments of the present invention. These diagrams merely illustrate examples, which should not unduly limit the scope of the claims herein. One of ordinary skill in the art would recognize many variations, alternatives, and modifications. As shown, the light emitting semiconductor device has a substrate comprising a surface region and a metal layer overlying the surface region of the substrate. The device has an interface region between the surface region and the metal layer. A textured characteristic is provided at or within a vicinity of the interface region. The device has a spatial spacing between the metal layer and the substrate to cause a coupling between electron-hole pairs generated in the substrate and a surface plasmon mode at the interface region. In a preferred embodiment, the device has a first electrode coupled to the substrate and a second electrode coupled to the metal layer. A voltage source 801 is coupled between the first electrode and the second electrode to generate electromagnetic radiation in the substrate, as illustrated in each of the Figures. Preferably, the electromagnetic radiation has been enhanced by the coupling between the electron-hole pairs generated by the substrate and the surface plasmon mode at the interface region. In a specific embodiment, the first electrode and the second electrode are separated by a spatial distance to cause a spatial charge distribution at the first electrode and to cause the surface plasmon mode at the second electrode.

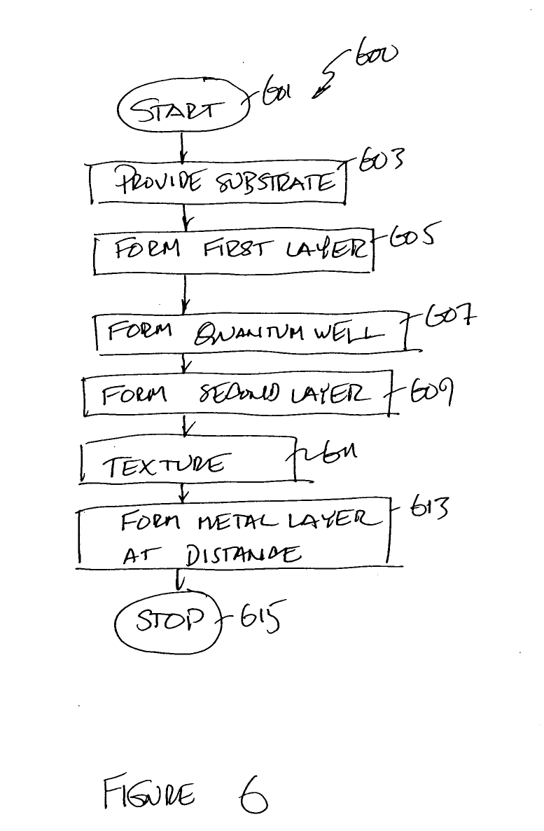

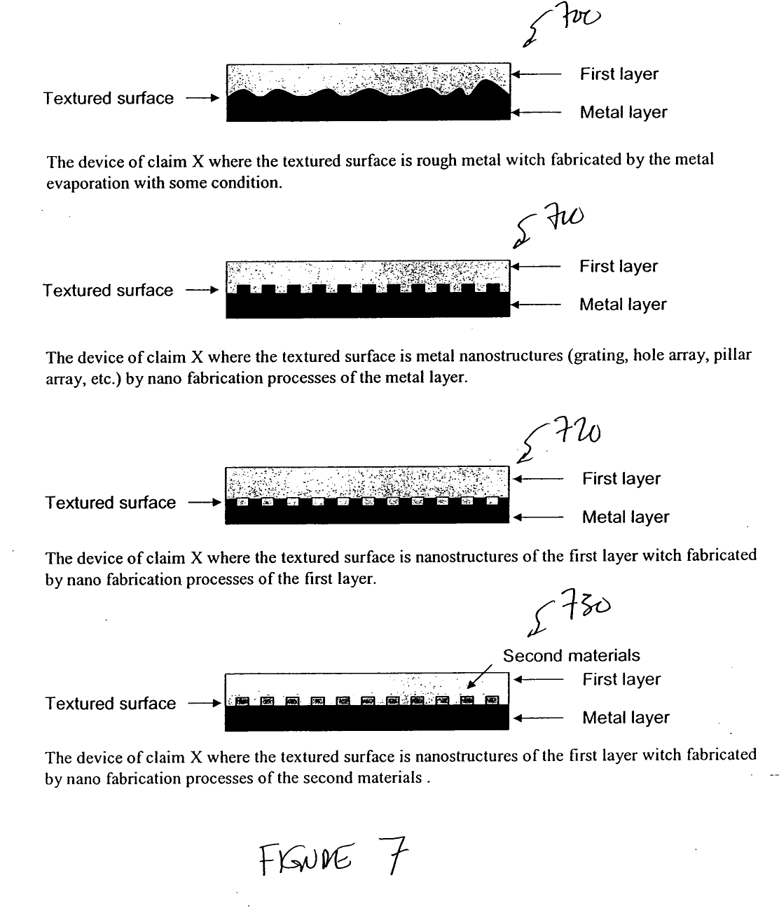

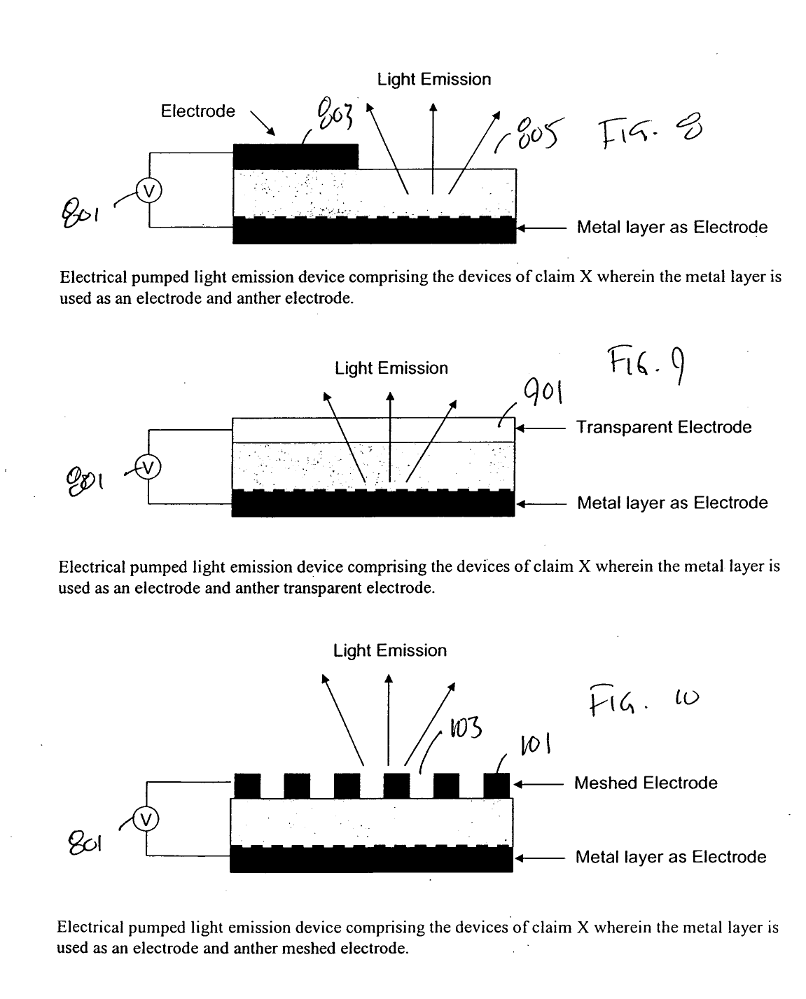

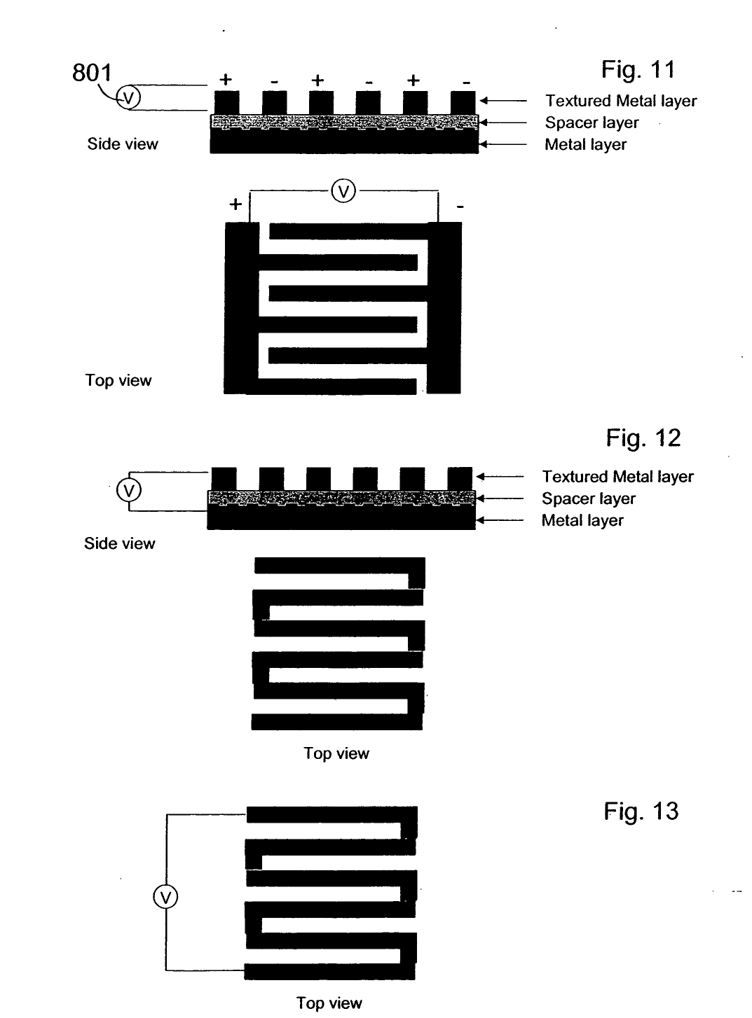

Depending upon the embodiment, various upper electrode structures may be provided on the device. As shown, the lower electrode has been formed on a backside surface of the substrate structure. In a specific embodiment, the electrode 803 covers a portion of the substrate, while maintaining other portions 805 free from the electrode, as illustrated by FIG. 8. As shown, the electrode has a light blocking characteristic, such as a metal, etc. In an alternative embodiment, the electrode structure is transparent 901, which is provided on the surface of the substrate, as illustrated by FIG. 9. The transparent electrode structure allows light to be emitted from the active region through the substrate and through the electrode, as shown. Depending upon the embodiment, the electrode can also be provided as a plurality of lines 101, which includes exposed regions 103 between each of the lines, as illustrated by FIG. 10. Depending upon the embodiment, the plurality of lines can each of the same voltage potential or altering voltage potentials, depending upon the embodiment, as illustrated by the simplified diagram of FIG. 11. That is, the plurality of lines can be configured as a plurality of two electrode structures, which are inter-digitated, as illustrated by FIG. 12. Alternatively, the plurality of lines can be a single serpentine structure, as illustrated by FIG. 13. Of course, there can be other variations, modifications, and alternatives.

One of the interesting advantages of surface plasmon enhancement techniques is that high emission efficiencies can be achieved even if the emission efficiency of original material were relatively low according to a specific embodiment. This property allows us to take advantage of many opportunities for using various new materials to emit light according to certain embodiments of the present invention. For example, light emitter of inelastic tunneling (LEIT) based on the metal/insulator/metal structure without semiconductor emitting materials are very simple and interesting devices, but have long been plagued by very low quantum efficiencies (<10⁻⁴). By using our surface plasmon coupling light enhancement and optimization of metal nanostructures, these efficiencies can be significantly enhanced and it should provide the unique super bright emitters with all-metal structures.

Preferably, surface plasmon enhancement of QW emission provides a method and resulting device for developing highly efficient solid-state light sources according to a specific embodiment. Even using unpatterned metal films, we have measured significant spontaneous recombination rate increases, and show how distance and choice of metals can be used to optimize and/or improve light emitters. We believe that surface plasmon coupling is an interesting methods for developing efficient LEDs, as the metal can be used both as electrical contact and for exciting plasmons. We believe that this work provides a foundation for the rapid development of highly efficient and high-speed solid-state light emitters, not limited only to the III-V materials. Of course, there can be other variations, modifications, and alternatives.

It is also understood that the examples and embodiments described herein are for illustrative purposes only. As described above, the present invention allows for enhanced emission of electromagnetic radiation using a coupling of surface plasmon modes, including resonance, and electron-hole interaction in the quantum well region according to a specific embodiment. In certain embodiments, the term active region and/or layer (i.e., emission region) a quantum wire, dot, disk, or a semiconductor hetero-structure according to an embodiment of the present invention. Although such coupling has been described, other mechanisms can also exist using the present technique according to a specific embodiment. Various modifications or changes in light thereof will be suggested to persons skilled in the art and are to be included within the spirit and purview of this application and scope of the appended claims.

Experiments:

To prove the principles and operation of the present invention, we performed various experiments. These experiments have been used to demonstrate the invention and certain benefits associated with the invention. As experiments, they are merely examples, which should not unduly limit the scope of the claims herein. One of ordinary skill in the art would recognize many variations, alternatives, and modifications. Details of these experiments are provided below.

We report a dramatic increase in the photoluminescence (PL) emitted from InGaN/GaN quantum wells (QW), obtained by covering these sample surface with thin metallic films. Remarkable enhancements of PL peak intensities were obtained from In_{0.3}Ga_{0.7}N QWs with 50 nm thick silver and aluminum coating with 10 nm GaN spacer. These PL enhancements can be attributed to strong interaction between QWs and surface plasmons (SPs). No such enhancements were obtained from samples coated with gold, as its well-known plasmon resonance occurs only at longer wavelengths. We also showed that QW-SP coupling increase the internal quantum efficiencies by measuring the temperature dependence of PL intensities. QW-SP coupling is a very promising method for developing the super bright light emitting diodes (LEDs). Moreover, we found that the metal nanostructure is very important facto to decide the light extraction. A possible mechanism of QW-SP coupling and emission enhancement has been developed, and high-speed and efficient light emission is predicted for optically as well as electrically pumped light emitters.

Since 1993, InGaN quantum wells (QW)-based light emitting diodes (LEDs) have been continuously improved and commercialized as light sources in the ultraviolet and visible spectral regions.¹⁻³ Moreover, white light LEDs, in which a blue LED is combined with a yellow phosphor, have been commercialized and offer a replacement for conventional incandescent and fluorescent light bulbs.⁴ However, the promise of inexpensive solid state lighting has so far been delayed by the relatively poor extraction efficiency of light from semiconductor light sources. We believe that the development of efficient and bright white LEDs will rapidly result in commercialization of efficient solid state illumination sources. The most important requirement for a competitive LED for solid state lighting is the development of new methods to increase its quantum efficiency of light emission.

The external quantum efficiency (Cₑₓₜ) of light emission from an LED is given by the light extraction efficiency (Cₑₓₜ) and internal quantum efficiency (ηᵢₙₜ). ηᵢₙₜ in turn is determined by the ratio of the radiative (K_{rad}) and nonradiative (Kₙₒₙ) recombination rates of carriers.

$${n}_{ext} = {C}_{ext} \times {n}_{int} = {C}_{ext} \times \frac{{k}_{rad}}{{k}_{rad} + {K}_{non}} \qquad ( 1 )$$

Often, kₙₒₙ is faster than k_{rad} at room temperature, resulting in modest ηᵢₙₜ. There are three methods to increase Cₑₓₜ; (1) increase Cₑₓₜ, (2) decrease kₙₒₙ, or (3) increase k_{rad}. Previous work has focused on improving Cₑₓₜ from InGaN LEDs by using the patterned sapphire substrates and mesh electrodes.⁵ However, further improvements of extraction of light through these methods are rapidly approaching fundamental limitations. Although much effort has recently been placed into reducing kₙₒₙ by growing higher quality crystals,⁶⁻⁷ dramatic enhancements of Cₑₓₜ have so far been elusive.⁸⁻⁹ On the other hand, there have been very few studies focusing on increasing k_{rad,}¹⁰⁻¹¹ though that could prove to be most effective for development of high Cₑₓₜ light emitters. In this article, we propose the enhancement of k_{rad} by coupling between surface plasmon (SP) and the InGaN QWs. If the plasmon frequency is carefully selected to match the QW emission frequency, the increase of the density states resulting from the surface plasmon dispersion diagram can result in large enhancements of the spontaneous emission rate. Therefore, energy coupling between QW and surface plasmon as described in this article is one of the most promising solutions to increase k_{rad}.

Surface plasmons, excited by the interaction between light and metal surfaces,¹²⁻¹³ are known to enhance absorption of light in molecules¹⁴, increase Raman scattering intensities¹⁵⁻¹⁶ and light transparencies,¹⁷⁻¹⁸ and also generate photonic bandgap.¹⁹⁻²⁰ Since 1990, surface plasmons have also received much attention when used in LEDs.²¹⁻³⁰ Gianordoli et al. optimized the emission characterization of GaAs-based LED by SP.²⁵ Vuckovic et al. reported the surface plasmon enhanced LED analyzing by both theoretically and experimentally.²⁶ Thus, great attention has been focused on surface plasmon enhanced emission. Hobson et al. reported the surface plasmon enhanced organic LEDs.²⁷ For InGaN QWs, Gontijo and co-workers reported the coupling of the spontaneous emission from QW into the surface plasmon on silver thin firm²⁸ and showed increased absorption of light at the surface plasmon frequency. Neogi et al. confirmed that the recombination rate in an InGaN/GaN QW could be significantly enhanced by the time-resolved PL measurement.²⁹ However, in this early work, light could not be extracted efficiently from the silver/GaN surface. Therefore, the actual PL enhancement of InGaN/GaN by coupling into surface plasmon had not so far been observed directly. Quite recently, we have reported for the first time large photoluminescence (PL) increases from InGaN/GaN QW material coated with metal layers.³⁰ In order to design even more efficient structures and to fabricate electrically pumped LED devices by using surface plasmon coupling, we have to understand and optimize both mechanism and dynamics of energy transfer and light extraction. Here we fabricate and test nanostructured metal layers to explore the dependence of the plasmon enhancement on metal composition, thickness, and grain shapes and sizes. The purpose of this work is to predictably use our control over metal geometries and composition to improve light emission and localization.

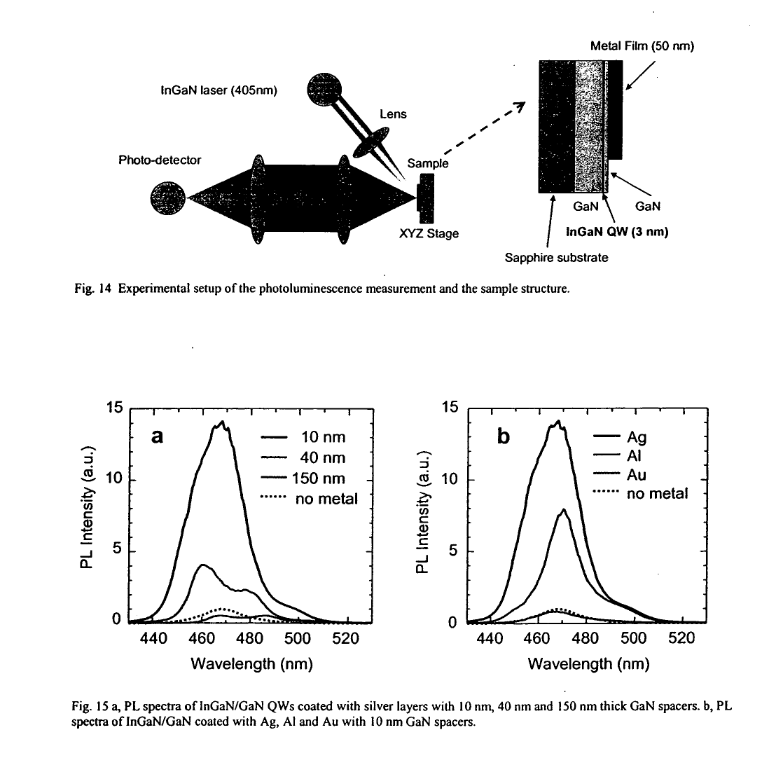

FIG. 14 shows the setup of the PL measurement and the sample structure. In_{0.3}Ga_{0.7}N/GaN QW wafers were grown on a (0001) oriented sapphire substrate by a metal-organic chemical vapor deposition (MOCVD). The QW heterostructure consists of a GaN (4 μm) buffer layer, an InGaN QW (3 nm) and a GaN cap layer (10, 40 or 150 nm), and the PL peak wavelength of the wafers is located at 470 nm. A 50 nm thick silver film was evaporated on top of the surface of these wafers. After polishing the bottom surface of the QW samples, we photoexcite and detect emission from the backside of the samples through the transparent substrate. Such back side access to the QWs permit us the rapidly compare the PL from QWs with and without the influence of surface plasmons, and to measure the dependence of the emission intensity on the distance between the QW and the metal films by changing the GaN spacer thickness. Topography measurements were performed by a twin-SNOM system manufactured by OMICRON. Fluorescence microscopy was used with ×40 objective, a mercury lamp, and a color CCD camera. Metal grating structures were fabricated by electron beam lithography on a 50 nm thick polymethylmethacrylate (PMMA) mask coated on the metal surface. The pattern was transferred into the top metal layer by using Ar ion milling. To perform the photoluminescence (PL) measurements, a cw-InGaN diode laser (406 nm) was used to excite the QWs from the bottom surface of wafer. Luminescence was collected and focused into an optical fiber and subsequently detected with a multichannel spectrometer (Ocean optics). Neutral density filters were used to vary the excitation power (from 0.18 to 4.5 mW) to determine the power dependence of the luminescence intensities, and their temperature dependence was studied by using a by cryostat with the ability of cooling from room temperature to 6K. To perform time-resolved PL measurements, frequency doubled beams of a mode-locked Al₂O₃:Ti laser pumped by an Ar⁺ laser were used to excite the QW from the backside of the wafer. A 1.5 ps pulse width, 400 nm pump wavelength, and 80 MHz repetition rate were chosen to excite luminescence in the QW. A streak camera system (Hamamatsu) was used as the detector.

Enhanced Photoluminescence Spectra

FIG. 15a shows typical emission spectra from InGaN/GaN QW samples covered with silver layers. As the PL peak of the uncoated wafer at 470 nm was normalized to 1, it is clear that a dramatic enhancement in the PL intensity from the silver coated InGaN QWs can be obtained when the cap layer thicknesses is limited to 10 nm. On the other hand, the PL intensities are no longer strongly influenced from the silver in samples with 150 nm thick cap layers. The enhancement ratios of 10 nm capped QW samples covered with silver are 14-fold at the peak wavelength and 17-fold when comparing the luminescence intensity integrated over the emission spectrum with un-coated InGaN samples. We also compared the PL spectra of our QW samples after coating them with silver, aluminum, and gold layers (FIG. 15b). For InGaN QWs with a 10 nm cap, such measurements indicate that a 8-fold peak intensity and 6-fold integrated intensity enhancement is obtained after coating with aluminum, and no enhancement in PL is found to occur in gold-coated samples. In such a measurement, a small (2×) increase in the luminescence efficiency could be expected after metallization as the deposited metal reflects light back into the QW, and this may double the effective path-length of the incident pump light. Although the reflectivity of gold at 470 nm is smaller than that of silver or aluminum, this difference alone cannot explain the large difference in the enhancement ratio of each metal.

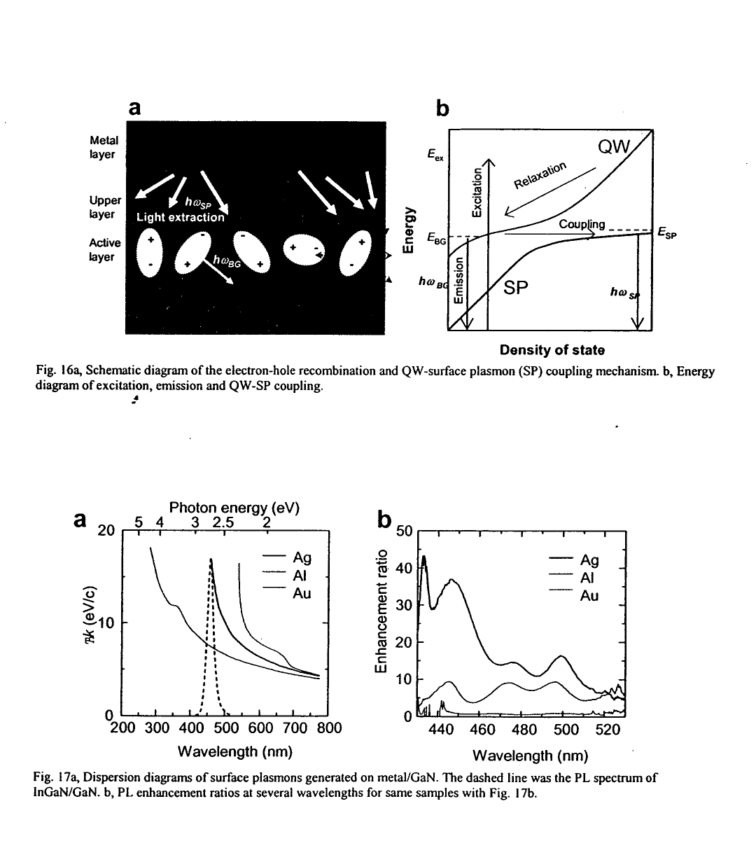

The dramatic PL enhancement of samples after coating with Ag and Al can be attributed to the strong interaction between the QW and surface plasmons. We propose a possible mechanism of QW-SP coupling and light extraction shown in FIG. 16a, which we had noted above. Electron-hole pairs created in the QW can couple to the electron vibration at the metal/semiconductor surface when the bandgap energy (h-ω_{SP}) of InGaN active layer is close to the electron vibration energy (h-ω_{SP}) of surface plasmon. Then, electron-hole recombination may produce a SP instead of a photon, and this new path of the recombination increases the spontaneous recombination rate. If the metal/semiconductor surface were perfectly flat, it would be difficult to extract light emission from the surface plasmon, since it is a non-propagating evanescent wave. However, in evaporated metal coatings, light emission can be observed as the surface plasmon is scattered through roughness and imperfections in the metal layers. The coupling rate (k_{SP}) between the QW and surface plasmon is expected to be much faster than k_{rad} as a result of the large electromagnetic fields introduced by the large density of states (FIG. 16b). Actually, we observed such the enhanced spontaneous emission rates by the time-resolved PL measurement. All profiles could be fitted to single exponential functions and PL lifetimes (τ_{PL}) were obtained. We found that the time-resolved PL decay profiles of the Ag-coated sample strongly depend on the wavelength and become faster at shorter wavelengths, whereas those of the uncoated sample show little spectral dependence.³¹ We attribute the increases in both emission intensities and decay rates from Ag-coated samples to the coupling of energy between the QW and the surface plasmon.

Surface Plasmon Dispersion Diagram

The dispersion diagrams of the surface plasmon modes at the metal/GaN interfaces are shown in FIG. 17a. The surface plasmon wave-vector (momentum) k(ω) was obtained by the following equation.¹²⁻¹³

$$k ( ϖ ) = \frac{ω}{c} \sqrt{\frac{{ɛ}_{metal}^{′} ( ω ) {ɛ}_{GaN}^{′} ( ω )}{{ɛ}_{metal}^{′} ( ω ) + {ɛ}_{GaN}^{′} ( ω )}} \qquad ( 2 )$$

where, ε′ₘₑₜₐₗ(ω) and ε′_{GaN}(ω) are the real part of the dielectric functions for metal and GaN, respectively. The plasmon energy (h-ω_{P}) of silver is well known as 3.76 eV.³² The surface plasmon energy (h-ω_{SP}) must be modified for a silver/GaN surface, and can be estimated to be approximately ˜2.8 eV (˜440 nm) (FIG. 4a) when using the dielectric constant of silver³³ and GaN³⁴. k(ω) approaches infinity around ˜2.8 eV by ε′ₘₑₜₐₗ(ω)+ε′_{GaN}(ω)˜0. We have plotted a typical measured PL spectrum from the InGaN QW in FIG. 17a. The position of the PL peak was very close to h-ω_{SP}, and large surface plasmon enhancements in luminescence intensity were observed especially at the higher energy side of the PL spectrum. This observation supports the existence of the QW-SP coupling phenomenon. Thus, silver is suitable for surface plasmon coupling to blue emission, and we attribute the large increases in luminescence intensity from Ag-coated samples to such resonant surface plasmon excitation. In contrast, the estimated h-ω_{SP} of gold on GaN is below ˜2.2 eV (˜560 nm), and no measurable enhancement is observed in Au-coated InGaN emitters as the surface plasmon and QW energies are not matched. In the case of aluminum, the h-ω_{SP} is higher than ˜5 eV (˜250 nm), and the real part of the dielectric constant is negative over a wide wavelength region for visible light.³⁵ Thus, a substantial and useful PL enhancement is observed in Al-coated samples, although the energy match is not ideal at 470 nm and a better overlap is expected at shorter wavelengths. FIG. 17b shows the enhancement ratios of PL intensities with metal layers separated from the QWs by 10 m spacers as a function of wavelength. We find that the enhancement ratio increases at shorter wavelengths for Ag samples, while it is independent of wavelength for Al coated samples. The clear correlation between FIGS. 17a and 17b suggests that the obtained emission enhancement with Ag and Al is due to surface plasmon coupling.
Spacer Trickiness and Excitation Power Dependences

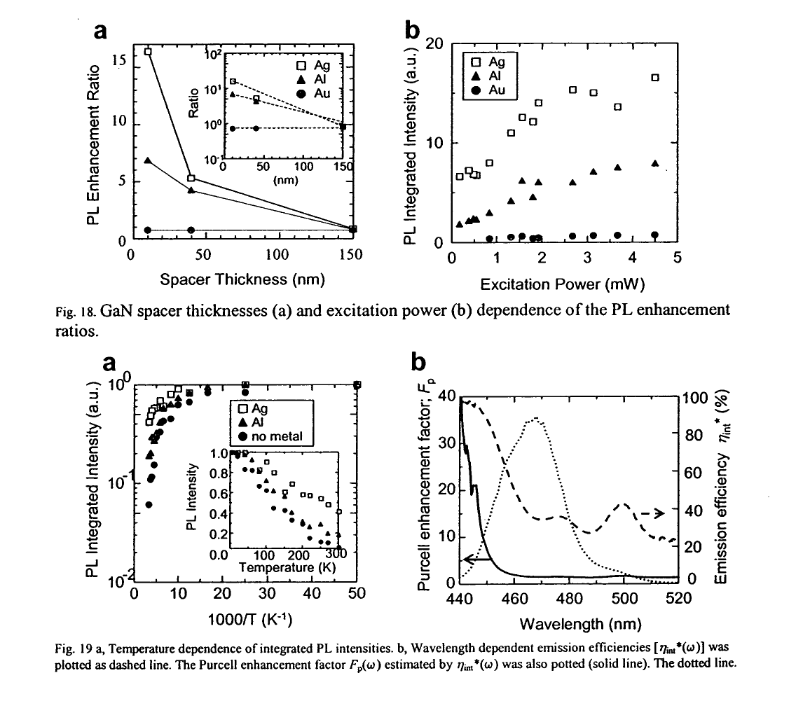

PL intensities of Al and Ag coated samples were also found to strongly depend on the distance between QWs and the metal layers, in contrast to Au coated samples. FIG. 18a shows this dependence of the PL enhancement ratios taken for three different GaN spacer thicknesses (of 10 nm, 40 nm, and 150 nm) with each metal coating. These show an exponential increase in intensity as the spacer thickness is decreased for Ag and Al, but no significant improvement in the PL intensity for samples coated with gold. This figure suggests that coupling between surface plasmon should be main component to contribute to the PL enhancement, because the surface plasmon is an evanescent wave, which decays exponentially with increasing distance from the metal surface. Only electron-hole pairs located within the near-field from the surface can couple to the surface plasmon mode. The penetration depth Z(ω) of the surface plasmon fringing field into GaN from metal can be calculated from¹¹⁻¹²

$$Z ( ω ) = \frac{c}{ω} \sqrt{\frac{{ɛ}_{GaN}^{′} ( ω ) - {ɛ}_{metal}^{′} ( ω )}{{{ɛ}_{metal}^{′} ( ω )}^{2}}} \qquad ( 3 )$$

Z(ω) is predicted to be Z=47, 77, and 33 nm for Ag, Al, and Au, respectively at 470 nm. The inset of FIG. 18a shows good agreement between these calculated penetration depths (dashed lines) and measured values for Ag and Al coated samples. This again indicates that the emission enhancement results from QW-SP coupling.

We also find that the luminescence enhancement ratio increases with increasing excitation power (FIG. 18b). In InGaN QWs, electron-hole pairs are often localized by spatial modulations in bandgap energy produced by fluctuations of indium composition, QW width, or piezoelectric field. Such localization centers serve as radiative recombination centers for electron-hole pairs and explain the strong emission and insensitivity to growth defects in InGaN/GaN QW material. The emission efficiency may be reduced at high excitation intensities by saturation of these localization centers. When metal layers are coated within the near field of the QW, both localized and un-localized electron-hole pairs can immediately couple to the surface plasmon mode. In that situation, the saturation of the localized centers can be avoided and this leads to high emission efficiencies even under intense excitation. We consider this very advantageous in light emitting diodes, since generally the emission efficiencies of such emitters are reduced under the high current pumping. Thus, by using the surface plasmon coupling, higher current operation and brightness should be achievable.

Internal Quantum Efficiencies and Purcell Enhancement Factor

We expect that the surface plasmon coupling will increase the efficiency (ηᵢₙₜ) by enhancing the spontaneous recombination rate. In order to estimate the ηᵢₙₜ and to separate the surface plasmon enhancement from other effects (mirror effect, photon recycling, etc.), we have also measured the temperature dependence of the PL intensity. FIG. 19a shows the linear and Arrhenius plots of the integrated photoluminescence intensities of InGaN-SQWs coated with Ag and Al and compares these to un-coated samples with 10 nm GaN spacer layer thicknesses. The ηᵢₙₜ values of un-coated InGaN was estimated as 6% at room temperature by assuming ηᵢₙₜ˜100% at ˜6 K.³⁶ We found that the ηᵢₙₜ values were increased by 6.8 times (41%) by Ag coating and by 3 times (18%) by Al coating. We expect this actual enhancement of the ηᵢₙₜ values to be a result of the enhancement of the spontaneous recombination rate of electron-hole pairs by surface plasmon coupling. 6.8-fold increasing of ηᵢₙₜ means that 6.8-fold improvement of the efficiency of electrically pumped LED devices should be achievable because ηᵢₙₜ is a fundamental property and not depend on the pumping method. Such improved efficiencies of the white LEDs, in which a blue LED is combined with a yellow phosphor, are expected to be larger than those of current fluorescent lamps or light bulbs. The luminous efficacy of commercial white LEDs is 25 lm/W under a current of 20 mA at room temperature.³⁷ This value is still lower than that of fluorescent tubes (75 lm/W). A 3-fold improvement is necessary to exceed the current fluorescent lamps or light bulbs. We expect that the surface plasmon coupling technique is very promising for even larger improvements of solid-state light source.

Wavelength depended enhanced efficiencies ηᵢₙₜ*(ω) can be related the coupling rate k_{SP}(ω) between QWs and surface plasmons by the relationship:

$${η}_{int}^{*} ( ω ) = \frac{{k}_{rad} ( ω ) + {C}_{est}^{′} ( ω ) {k}_{SP} ( ω )}{{k}_{rad} ( ω ) + {k}_{non} ( ω ) + {k}_{SP} ( ω )} \qquad ( 4 )$$

where C″ₑₓₜ(ω) is the probability of photon extraction from the surface plasmons energy and is decided by the ratio of light scattering and dumping of electron vibration through non-radiative loss. FIG. 19b shows the ηᵢₙₜ*(ω) of Ag coated sample estimated from PL enhancement ratio (FIG. 19b) by normalizing the integrated ηᵢₙₜ* should be 41%. We find that ηᵢₙₜ*(ω) increases at shorter wavelengths where the plasmon resonance more closely matches the QW emission, and reaches almost 100% at 440 nm.

The Purcell enhancement factor Fₚ³⁸ quantifies the increase in the spontaneous emission rate of a mode for a particular mode, and can be described by ηᵢₙₜ(ω) and ηᵢₙₜ*(ω) when C″ₑₓₜ≈1:

$${F}_{p} ( ω ) = \frac{{k}_{rad} ( ω ) + {k}_{non} ( ω ) + {k}_{SP} ( ω )}{{k}_{rad} ( ω ) + {k}_{non} ( ω )} \approx \frac{1 - {η}_{int} ( ω )}{1 - {η}_{int}^{*} ( ω )} \qquad ( 5 )$$

FIG. 19b also shows Fₚ(ω) estimated at each wavelength by assuming a constant ηᵢₙₜ(ω)=6%. Fₚ(ω) is significantly higher at wavelengths below 470 nm, well in agreement with previous work²⁸⁻²⁹. The PL spectrum shape (plotted as dotted line) also indicates that Fₚ(ω) values are higher at the shorter wavelength region. That should be a possible reason for the asymmetry in the luminescence peak of FIG. 19. FIG. 19b suggests that a InGaN QW with a peak position at around 440 nm should be best matched for surface plasmon enhancement from a silver layer. In that case, the enhanced ηᵢₙₜ*(ω) value is expected to approach 100% throughout the PL spectrum. The surface plasmon frequency could be geometrically tuned to match our λ˜470 nm QW by fabricating nanostructures, for example, using a grating structure, or using alloys.
Surface Roughness and Grating Structures

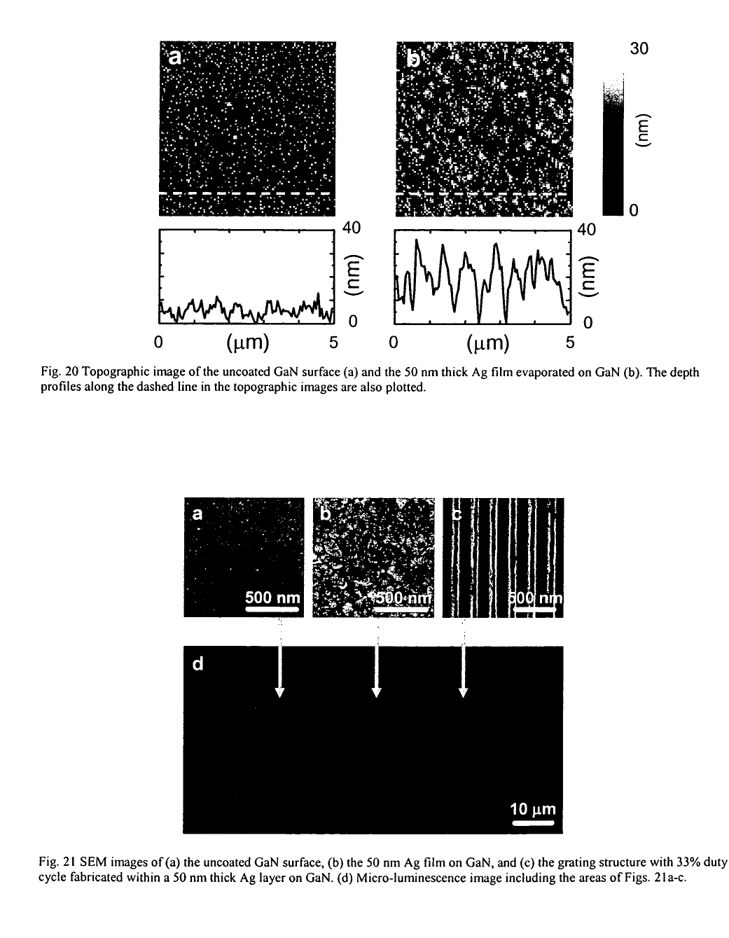

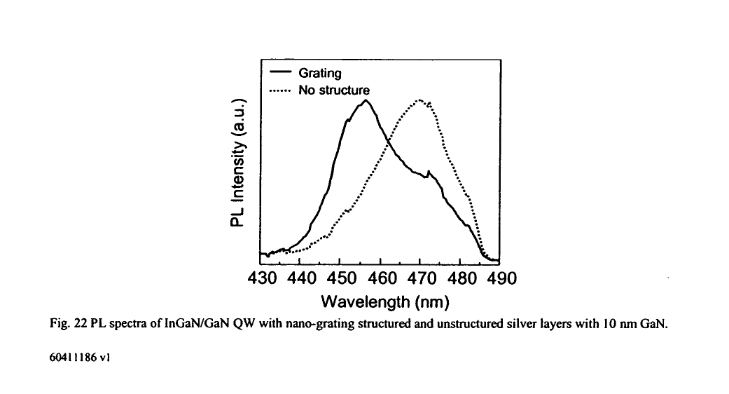

The surface plasmon energy can be extracted as light by providing roughness or nano-structuring the metal layer. Such roughness allows surface plasmons of high momentum to scatter, lose momentum and couple to radiated light.³⁹ C″ₑₓₜ(ω) in Eq. (4) should depend on the roughness and nano-structure of the metal surface. We succeeded in controlling the grain structure within nano-sizes. Such roughness in the metal layer was observed from topographic images obtained by shear-force microscopy of the original GaN surface (FIG. 20a) and the coated Ag surface (FIG. 20b). The depth profiles along the dashed lines of the Ag surface of approximately 30-40 nm while the GaN surface roughness was below 10 nm. Higher magnification SEM images of Ag and GaN surface are shown in FIGS. 21a and 21b. The length scale of the roughness of Ag surface was determined to be a few hundred nanometers. FIG. 21c shows a fabricated metal grating, a geometry that has previously been used to couple surface plasmon and photons^{21, 23-26} Micro-luminescence images of uncoated, coated, and patterned grating structures of Ag on InGaN QWs with 10 nm spacers are shown in FIG. 21d. We found a doubling of the emission from 133 nm wide Ag stripes forming a 400 nm period grating, whereas such an emission increase was not observed from 200 nm wide Ag stripes within a 600 nm period grating. This measurement suggests that the size of the metal structure determines the surface plasmon-photon coupling and light extraction. We also found that the PL peak position of grating structured regions was dramatically blue-shifted (FIG. 22). This suggests that the nano-grating structure modulate not only light extraction but also localized surface plasmon frequency. Such geometrical tuning of the surface plasmon frequency is one of the most important next subjects and is now on progress by experimentally and theoretically.

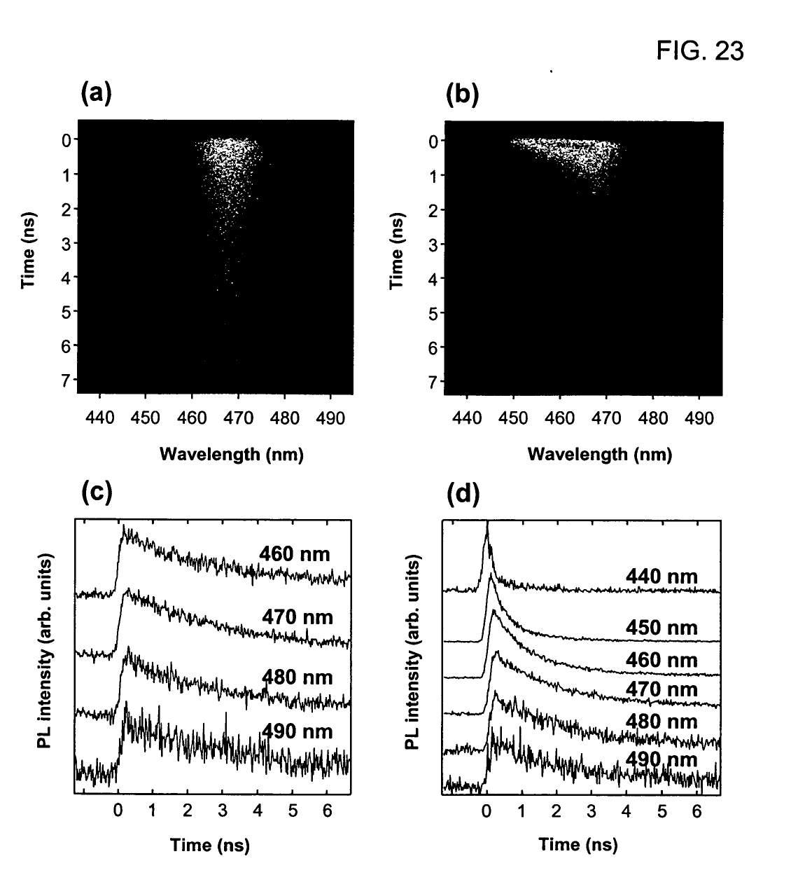

FIG. 23 shows the temporal-spectral profiles of (a) uncoated and (b) Ag-coated InGaN/GaN quantum well samples. This diagram is merely an illustration, which should not unduly limit the scope of the claims herein. One of ordinary skill in the art would recognize many variations, modifications, and alternatives. The streak camera output profile of each sample was quite different and the decay rates of Ag-coated samples were faster than those of uncoated samples. FIG. 23 (c) and (d) show the time-resolved PL decay profiles of both coated and uncoated quantum well emitters at several wavelengths. All profiles could be fitted to single exponential functions and PL lifetimes (τPL) were obtained. We found that the decay profiles of the Ag-coated sample strongly depend on the wavelength and become faster at shorter wavelengths, whereas those of the uncoated sample show little spectral dependence. We attribute the increases in both emission intensities and decay rates from Ag-coated samples to the coupling of energy between the quantum well and the surface plasmon mode. We find that τPL values from metal coated samples become much shorter at lower wavelengths, with the fastest emission rate of τPL ˜200 ps observed at 440 nm. We observe a 32-fold enhancement of the PL decay rate (Fp=32) at 440 nm, indicating that the Δint* should be almost 100%. Other techniques to enhance the InGaN emission rates have already been reported by Walterelt and co-workers, who pioneered piezo-electric field free GaN/AlGaN QW grown on M-plane of GaN substrate 40 and observe about 10-times faster PL decay. Wierer and co-workers have also reported InGaN/GaN LEDs within a photonic crystal, and report ˜1.5 fold increases in light extraction 41. Ultimately, these techniques can be enhanced by the QW-SP coupling technique described here to obtain even higher Fp factor emitters. Of course, there can be other variations, modifications, and alternatives.

### CONCLUSIONS

We conclude that the surface plasmon enhancement of PL intensities of InGaN is a very promising method for developing solid state light sources with high emission efficiencies. We have directly measured significant enhancements of ηᵢₙₜ and the spontaneous recombination rate, and shown how distance and choice of patterned metal films can be used to optimize light emitters. Even when using un-patterned metal layers, the surface plasmon energy can be extracted by the submicron scale roughness on the metal surface surface plasmon coupling is one of the most interesting solutions for developing efficient photonic devices, as the metal can be used both as an electrical contact and for providing high electromagnetic fields from surface plasmons. We believe that this work provides a foundation for the rapid development of highly efficient and high-speed solid state light emitters alternative to conventional light bulbs.

It is also understood that the examples and embodiments described herein are for illustrative purposes only. As merely an example, the claimed metal layer according to a specific embodiment can comprise a titanium, tungsten, copper, platinum, chromium, palladium, or other metal bearing material. Such material is associated with a preselected wavelength of the electromagnetic radiation. Additionally, the active layer/semiconductor layers can be made of any combination of materials such as InGaN/GaN, GaN/AlGaN, ZnCdSe/ZnSe, InGaAs/GaAs, GaAs/AlGaAs, InGaAlP/GaP, ZnCdO/ZnO, Si/SiO2, doped-SiC/SiC, and other combinations of active/semiconductor materials. Additionally, the semiconductor material can be organic, inorganic, polymer, amorphous, glass and other combination of materials instead of semiconductor materials according to specific embodiments. The active/semiconductor layers combination comprises light-emitting/carrier transporting materials of organic, inorganic, polymer, amorphous, glass and other combination of materials instead of semiconductor materials according to other embodiments. Additionally, the first semiconductor material is a hole transporting layer (HTL) and the second semiconductor material is an electron transporting layer (ETL), or the first semiconductor material is an ETL and the second semiconductor material is a HTL according to other embodiments. In still other embodiments, the final device and method of manufacture can include, but is not limited to light-emitting diode (LED) structures, organic light-emitting diode (OLED) structures, light emitter of inelastic tunneling (LEIT) structures, and the like. In other embodiments, the devices can be used for non-linear optical materials such as frequency doubler, tripler, optical parametric materials, and others. In a specific embodiment, the device and methods of manufacture can also be applied to a high-speed optical modulator and switch (e.g., modulate amplitude, polarization, direction, and others), including high-speed and high-sensitive photo-detector. Various modifications or changes in light thereof will be suggested to persons skilled in the art and are to be included within the spirit and purview of this application and scope of the appended claims.

### REFERENCES

1. S. Nakamura, T. Mukai and M. Senoh, “Candela-class high-brightness InGaN/AlGaN double-heterostructure blue-light-emitting diodes”, Appl. Phys. Lett. 64, 1687-1689, 1994.
2. S. Nakamura, T. Mukai, M. Senoh and N. Iwase, “High-brightness InGaN/AlGaN double-heterostructure blue-green-light-emitting diodes”, J. Appl. Phys. 76, 8189-8191, 1994.
3. T. Mukai, M. Yamada, S. Nakamura, “Current and temperature dependences of electroluminescence of InGaN-based UV/blue/green light-emitting diodes”, Jpn. J. Appl. Phys. 37, L1358-L1361, 1998.
4. S. Nakamura and G. Fasol, The blue laser diode: GaN based light emitting diode and lasers, Springer, Berlin, 1997.
5. M. Yamada, T. Mitani, Y. Narukawa, S. Shioji, I. Niki, S. Sonobe, K. Deguchi, M. Sano, and T. Mukai, “InGaN-based near-ultraviolet and blue-light-emitting diodes with high external quantum efficiency using a patterned sapphire substrate and a mesh electrode”, Jpn. J. Appl. Phys. 41, L1431-L1433, 2002.
6. S. Nakamura, “The roles of structural imperfections in InGaN-based blue light-emitting diodes and laser diodes”, Science, 281, 956-961, 1998.
7. S. Nakamura, M. Senoh, S. Nagahama, N. Iwasa, T. Yamada, T. Matsushita, H. Kiyoku, Y. Sugimoto, T. Kozaki, “InGaN/GaN/AlGaN-based laser diodes with modulation-doped strained-layer superlattices grown on an epitaxially laterally overgrown GaN substrate”, Appl. Phys. Lett. 72, 211-213, 1998.
8. T. Mukai, K. Takekawa, S. Nakamura, “InGaN-based blue light-emitting diodes rrown on epitaxially laterally overgrown GaN substrates”, Jpn. J. Appl. Phys. 37, L839-L841, 1998.
9. T. Mukai, and S. Nakamura, “ultraviolet InGaN and GaN single-quantum-well-structure light-emitting diodes grown on epitaxially laterally overgrown GaN substrates”, Jpn. J. Appl. Phys., 38, 5735-5739, 1999.
10. P. Walterelt, O. Brandt, A. Trampert, H. T. Grahn, J. Menniger, M. Ramsteiner, M. Reiche, and K. H. Ploog, “Nitride semiconductors free of electrostatic fields for efficient white light-emitting diodes”, Nature, 406, 865-868, 2000.
11. J. J. Wierer, M. R. Krames, J. E. Epler, N. F. Gardner, M. G. Craford, J. R. Wendt, J. A. Simmons, and M. M. Sigalas, “InGaN/GaN quantum-well heterostructure light-emitting diodes employing photonic crystal structures” Appl. Phys. Lett., 84, 3885-3887, 2004.
12. H. Raether, Surface plasmon on smooth and rough surface and on grating, Springer, Berlin, 1988.
13. A. Liebsch, Electronic Excitations at Metal Surfaces, Physics of Solids and Liquids, Ansgar, Libsch, 1997
14. G. W. Ford and W. H. Weber, “Electromagnetic-interactions of molecules with metal-surfaces”, Phys. Rep. 113, 195-287, 1984.
15. M. Fleischmann, P. J. Hendra, and A. J. McQuillan, “Raman spectra of pyridine adsorbed at a silver electrode”, Chem. Phys. Lett. 26, 163-166, 1974.
16. J. F. García-Vidal, and J. B. Pendry, “Collective theory for surface enhanced Raman scattering”, Phys. Rev. Lett. 77, 1163-1166, 1996.
17. T. W. Ebbesen, H. J. Lezec, H. F. Ghasemi, T. Thio, and P. A. Wolff, “Extraordinary optical transmission through sub-wavelength hole arrays”, Nature, 391, 667-669, 1998.
18. U. Schroter and D. Heitmann, “Surface-plasmon-enhanced transmission through metallic gratings”, Phys. Rev. B, 58, 15419-15421, 1998.
19. S. C. Kitson, W. L. Barnes, and J. R. A. Sambles, “full photonic band gap for surface modes in the visible”, Phys. Rev. Lett. 77, 2670-2673, 1996.
20. W. T. Barnes, T. W. Preist, S. C. Kitson, and J, R. Sambles, “Physical origin of photonic energy gap in the propagation of surface plasmon on grating”, Phys. Rev. B. 54, 6227-6244, 1996.
21. A. Köck, E. Gornik, M. Hauser, and M. Beinstingl, “Strongly directional emission from AlGaAs/GaAs light-emitting diode”, Appl. Phys. Lett. 57, 2327-2329, 1990.
22. N. E. Hecker, R. A. Hopfel, and N. Sawaki, Physica E, “Enhanced light emission from a single quantum well located near a metal coated surface”, 2, 98-101, 1998.
23. N. E. Hecker, R. A. Hopfel, N. Sawaki, T. Maier, and G. Strasser, “Surface plasmon-enhanced photoluminescence from a single quantum well”, Appl. Phys. Lett. 75, 1577-1579, 1999.
24. W. L. Barnes, “Electromagnetic crystals for surface plasmon polaritons and the extraction of light from emissive devices”, J. Light. Tech., 17, 2170-2182, 1999.
25. S. Gianordoli, R. Hainberger, A. Kock, N. Finger, E. Gornik, C. Hank, and L. Korte, “Optimization of the emission characteristics of light emitting diodes by surface plasmons and surface waveguide modes”, Appl. Phys. Lett. 77, 2295-2297, 2000.
26. J. Vuckovic, M. Loncar, and A. Scherer, “Surface plasmon enhanced light-emitting diode”, IEEE J. Qunt. Elec. 36, 1131-1144, 2000.
27. P. A. Hobson, S. Wedge, J. A. E. Wasey, I. Sage, and W. L. Barnes, “Surface plasmon mediated emission from organic light emitting diodes”, Advanced Materials, 14, 1393-1396, 2002.
28. I. Gontijo, M. Borodisky, E. Yablonvitch, S. Keller, U. K. Mishra, and S. P. DenBaars, “Enhancement of spontaneous recombination rate in a quantum well by resonant surface plasmon coupling” Phys. Rev. B, 60, 11564-11567, 1999.
29. A. Neogi, C.-W. Lee, H. O. Everitt, T. Kuroda, A. Tackeuchi, and E. Yablonvitch, “Enhancement of spontaneous recombination rate in a quantum well by resonant surface plasmon coupling”, 66, 153305, 2002.
30. K. Okamoto, I. Niki, A. Shvartser, Y. Narukawa, T. Mukai, A. Scherer, “Surface-plasmon-enhanced light emitters based on InGaN quantum wells”, Nature Mater., 3, 601-605, 2004.
31. K. Okamoto, I. Niki, Y. Narukawa, T. Mukai, Y. Kawakami, and A. Scherer, “Surface plasmon enhanced high-speed spontaneous emission”, submitted for publication
32. A. Liebsch, “Surface plasmon dispersion of Ag”, Phys. Lev. Lett, 71, 145-148, 1993.
33. E. D. Palik, Handbook of Optical Constants of solids, Academic, San Diego, 1985.
34. T. Kawashima, H. Yoshikawa, S. Adach, S. Fuke, and K. Ohtsuk, “Optical properties of hexagonal GaN”, J. Appl. Phys., 82, 3528-3535, 1997.
35. A. Bagchi, C. B. Duke, P. J. Feibelman, and J. O. Porteus, “Measurement of Surface-Plasmon Dispersion in Aluminum by Inelastic Low-Energy Electron Diffraction”, Phys. Rev. Lett., 27, 998-1001, 1971.
36. Y. Kawakami, K. Omae, A. Kaneta, K. Okamoto, T. Izumi, S. Saijo, K. Inoue, Y. Narukawa, S. Nakamura, and S. Fujita, “Radiative and nonradiative recombination processes in GaN-based semiconductors”, Phys. Stat. Sol. (a), 183, 41-50, 2001.
37. Y. Narukawa, I. Niki, K. Izuno, M. Yamada, Y. Murazaki and T. Mukai, “hosphor-conversion white light emitting diode using InGaN near-ultraviolet chip”, Jpn. J. Appl. Phys. 37, L371-L373, 2003.
38. E. M. Purcell, “Spontaneous emission probabilities at radio frequencies”, Phys. Rev. 69, 681, 1946.
39. W. Barnes, “Light-emitting devices: Turning the tables on surface plasmons”, Nature Mater., 3, 588-589, 2004.
40. P. Waltereit, O. Brandt, A. Trampert, H. T. Grahn, J. Menniger, M. Ramsteiner, M. Reiche and K. H. Ploogp, “Nitride semiconductors free of electrostatic fields for efficient white light-emitting diodes”, Nature, 406, 865-868, 2000.
41. J. J. Wierer, M. R. Krames, J. E. Epler, N. F. Gardner, M. G. Craford, J. R. Wendt and J. A. Simmons, M. M. Sigalas, “InGaN/GaN quantum-well heterostructure light-emitting diodes employing photonic crystal structures”, Appl. Phys. Lett., 84, 3885-3887, 2004.

1. A light emitting semiconductor device comprising:
a substrate, the substrate comprising a surface region;
a first type semiconductor material overlying the surface region of the substrate;
an active layer overlying the semiconductor material;
a second type semiconductor material overlying the active layer;
a metal layer overlying the second type semiconductor material;
a surface region on the metal layer;
a spatial spacing between the metal layer and the active layer sufficient to cause an energy coupling between a surface plasmon mode at the surface region of the metal layer and the active layer;
a textured interface region between the metal layer and the second type of semiconductor material to enhance formation of electromagetic radiation from the surface plasmon mode;
whereupon the coupling causes an increase of a level of the electromagnetic radiation to be derived from the active layer.

2. The device of claim 1 wherein the active layer comprises a quantum well, the quantum well comprising an emission layer.

3. The device of claim 1 further comprising a textured surface region formed at the textured interface region on the metal layer interfacing the second type semiconductor material.

4. The device of claim 3 wherein the textured surface region is characterized by a roughness.

5. The device of claim 3 wherein the textured surface region is characterized by a plurality of spatial structures.

6. The device of claim 1 wherein the substrate is selected from quartz, silicon, glass, or sapphire.

7. The device of claim 1 wherein the substrate is optically transparent.

8. The device of claim 1 wherein the first semiconductor material is P-type and the second semiconductor material is N-type.

9. The device of claim 1 wherein the first semiconductor material comprises a gallium nitride material.

10. The device of claim 1 wherein the second semiconductor material comprises a gallium nitride material.

11. The device of claim 1 wherein the metal layer comprises a silver bearing material.

12. The device of claim 1 wherein the metal layer comprises a silver bearing material for a preselected wavelength of the electromagnetic radiation.

13. The device of claim 1 wherein the metal layer comprises an aluminum bearing material.

14. The device of claim 1 wherein the metal layer comprises an aluminum bearing material for a preselected wavelength of the electromagnetic radiation.

15. The device of claim 1 wherein the metal layer comprises a gold bearing material.

16. The device of claim 1 wherein the metal layer comprises a gold bearing material for a preselected wavelength of the electromagnetic radiation.

17. The device of claim 1 wherein the textured interface is provided on a portion of the second type of semiconductor material.

18. The device of claim 1 wherein the textured surface is provided on a portion of the metal layer.

19. The device 1 further comprising an electromagnetic radiation source coupled to the surface region.

20. The device of claim 1 further comprising a first electrode coupled to the first type semiconductor material and a second electrode coupled to the metal layer; and a voltage potential coupled between the first electrode and the second electrode.

21. A method for fabricating light emitting devices comprising:
providing a substrate, the substrate comprising a surface region;
forming a first type semiconductor material overlying the surface region of the substrate;
forming am active layer overlying the semiconductor material;
forming a second type semiconductor material overlying the active layer;
forming a textured interface region between the second type semiconductor material and a metal layer to be formed overlying the second type semiconductor material; and
forming a metal layer including a surface region overlying the second type semiconductor material at a spatial spacing between the surface region and the second type semiconductor material to cause a coupling between a surface plasmon mode at the surface region of the metal layer and the active layer;
whereupon the textured interface region enhances formation of a first electromagnetic radiation to be derived from the surface plasmon mode; and
whereupon the coupling associated with the spatial spacing between the surface region of the metal layer and the second type semiconductor material causes an increase of a level of second electromagnetic radiation to be derived from the active layer.

22. A light emitting semiconductor device comprising:
a substrate comprising a surface region and a semiconductor region;
a metal layer overlying the surface region of the substrate;
an interface region between the surface region and the metal layer;
a textured characteristic at the interface region;
a spatial spacing between the metal layer and the semiconductor region of the substrate to cause a coupling between electron-hole pairs generated in the semiconductor region of the substrate and a surface plasmon mode at the interface region.

23. The device of claim 22 wherein the semiconductor material comprises a semiconductor layer.

24. The device of claim 23 wherein the semiconductor material is selected from a group consisting of Si, Ge, SiC, GaN, InGaN, AlGaN, ZnSe, ZnCdSe, GaAs, AlGaAs, InGaAs, GaP, InGaAlP, AiN, and ZnO.

25. The device of claim 23 wherein the substrate further comprises a dielectric material, the semiconductor material being overlying the dielectric material.

26. The device of claim 25 wherein the dielectric material is selected from a group consisting of glass, quartz, SiO2, SiN, and quartz.

27. The device of claim 22 wherein the substrate comprises a polymer.

28. The device of claim 27 wherein the polymer is at least a molecule doped polymer.

29. The device of claim 22 wherein the first layer comprises a solution.

30. The device of claim 22 wherein the metal layer comprises a metal array.

31. The device of claim 22 wherein the textured surface characteristic enhances electromagnetic radiation to be derived from the surface plasmon mode.

32. The device of claim 22 wherein the substrate comprises a plurality of semiconductor quantum dots.

33. The device of claim 22 wherein the substrate comprises a plurality of active structures, each of the active structures including at least semiconductor quantum dot.

34. The device of claim 22 wherein the substrate comprises a p-type semiconductor layer and an n-type semiconductor layer.

35. The device of claim 22 wherein the substrate comprises a first layer, and overlying active layer, and an overlying second layer.

36. A light emitting semiconductor device comprising:
a first substrate comprising a first surface region;
a first metal layer overlying the first surface region of the first substrate;
a first interface region between the first surface region and the first metal layer;
a first textured characteristic at the first interface region;
a first spatial spacing between the first metal layer and the first substrate to cause a coupling between electron-hole pairs generated in the first substrate and a surface plasmon mode at the first interface region; and
a second substrate comprising a second surface region;
a second metal layer overlying the second surface region of the second substrate;
a second interface region between the second surface region and the second metal layer;
a second textured characteristic at the second interface region;
a second spatial spacing between the second metal layer and the second substrate to cause a coupling between electron-hole pairs generated in the second substrate and a surface plasmon mode at the second interface region.

37. The device of claim 36 further comprising:
an Nth substrate comprising an Nth surface region;
an Nth metal layer overlying the Nth surface region of the Nth substrate;
an Nth interface region between the Nth surface region and the Nth metal layer;
an Nth textured characteristic at the Nth interface region;
an Nth spatial spacing between the Nth metal layer and the Nth substrate to cause a coupling between electron-hole pairs generated in the Nth substrate and a surface plasmon mode at the Nth interface region;
whereupon N is an integer greater than 2.

38. The device of claim 37 wherein the first substrate, the second substrate, and the Nth substrate are arranged in a horizontal stacking configuration.

39. The device of claim 37 wherein the first substrate, the second substrate, and the Nth substrate are arranged in a vertical stacking configuration.

40. A method for manufacturing light emitting semiconductor devices, the method comprising:
providing a substrate comprising a surface region;
forming a metal layer overlying the surface region of the substrate, the metal layer and the surface region being characterized by a spatial spacing between the metal layer and the substrate to cause a coupling between electron-hole pairs generated in the substrate and a surface plasmon mode at an interface region between the metal layer and the surface region;
whereupon the interface region having a textured characteristic between the surface region and the metal layer.

41. The method of claim 40 wherein the metal layer is characterized by an uneven characteristic at the interface region.

42. The method of claim 41 wherein the uneven characteristic having a spatial feature indicative of a roughness and/or grains of the metal layer.

43. The method of claim 40 wherein the textured characteristic comprises a plurality of metal nanostructures.

44. The method of claim 40 wherein the textured characteristic comprises a plurality of metal nanostructures, the plurality of nanostructures being selected from a grating, an nano-array, a pillar array, and other structures.

45. The method of claim 40 further comprising forming a plurality of recessed regions in the surface region to form the textured characteristic at the interface region.

46. The method of claim 40 further comprising forming a plurality of nanostructures to form the textured characteristic at the interface region.

47. A light emitting semiconductor device comprising:
a substrate comprising a surface region, the substrate comprising an active region;
a metal layer overlying the surface region of the substrate;
an interface region between the surface region and the metal layer;
a textured characteristic at the interface region;
a spatial spacing between the metal layer and the active region of the substrate to cause a coupling between electron-hole pairs generated in the substrate and a surface plasmon mode at the interface region;
a first electrode coupled to the substrate;
a second electrode coupled to the metal layer; and
a voltage source coupled between the first electrode and the second electrode to generate electromagnetic radiation in the active region of the substrate, the electromagnetic radiation being enhanced by the coupling between the electron-hole pairs generated by the active region of the substrate and the surface plasmon mode at the interface region.

48. The device of claim 47 wherein the first electrode is transparent.

49. The device of claim 47 wherein the first electrode is overlying a portion of a backside surface of the substrate while maintaining an exposed portion of the backside surface.

50. The device of claim 47 wherein the first electrode is a meshed structure.

51. The device of claim 47 wherein the first electrode comprise a first first electrode structure comprising a plurality of first fingers and a first second electrode structure comprising a plurality of second fingers, the first fingers being interdigitated with the second fingers.

52. The device of claim 47 wherein the first electrode comprises a serpentine structure overlying the surface region.

53. The device of claim 47 wherein the first electrode and the second electrode are separated by a distance sufficient to cause the surface plasmon mode between the first electrode and the second electronde.

54. The device of claim 47 wherein the first electrode and the second electrode are separated by a spatial distance to cause a spatial charge distribution at the first electrode and to cause the surface plasmon mode at the second electrode.
